(19) United States
(12) Patent Application Publication
(10) Pub. No.: US 2009/0139558 A1
(43) Pub. Date: Jun. 4, 2009

(54) PHOTOELECTRIC CONVERSION DEVICE AND MANUFACTURING METHOD THEREOF

(76) Inventors: Shunpei YAMAZAKI, Tokyo (JP); Hisao IKEDA, Isehara (JP)

Correspondence Address: ERIC ROBINSON, PMB 955, 21010 SOUTHBANK ST., POTOMAC FALLS, VA, 20165, US

(21) Appl. No.: 12/273,653

(22) Filed: Nov. 19, 2008

(30) Foreign Application Priority Data
Nov. 29, 2007 (JP) 2007-308488

(51) Int. Cl. H01L 31/00; H01L 21/322

(52) U.S. Cl. 136/244; 438/57; 438/458; 257/E21.32

(57) ABSTRACT

It is an object of the present invention to provide a photoelectric conversion device with an excellent photoelectric converting characteristic while effectively utilizing silicon semiconductor material. A photoelectric conversion device comprises a first electrode, a first unit cell including a single-crystal semiconductor layer which is obtained by cleaving a single crystal semiconductor substrate at a damaged layer, a second unit cell including a non-single-crystal semiconductor layer, an intermediate layer including a transition metal oxide, and a second electrode, wherein the first unit cell and second unit cell are connected in series with the intermediate layer interposed therebetween and are sandwiched between the first electrode and the second electrode.

### BACKGROUND OF THE INVENTION

1. Field of the Invention

The present invention relates to a photoelectric conversion device including a single crystal semiconductor or a polycrystalline semiconductor and to a so-called tandem photoelectric conversion device in which a plurality of photoelectric conversion elements is stacked.

2. Description of the Related Art

The popularity of photovoltaic power generation has been increasing around the world as a countermeasure against global warming. Some photovoltaic power generation utilize solar heat, while many others employ photoelectric conversion devices (also called photovoltaic devices or solar cells) by which light energy is converted into electric energy with use of the photoelectric characteristic of a semiconductor.

The production of photoelectric conversion devices tends to increase year by year. For example, the total production of solar cells around the world in 2005 was 1759 MW, which is a drastic increase by 147% over the previous fiscal year. Above all, photoelectric conversion devices including a crystalline semiconductor have become popular worldwide and the devices including single crystal silicon substrates or polycrystalline silicon substrates account for a large part of the production.

As for a crystalline photoelectric conversion device which uses silicon as the material, a thickness of about 10 μm is enough for sunlight absorption. However, a single crystal silicon substrate or a polycrystalline silicon substrate manufactured as a product has a thickness of about 200 μm to 300 μm. That is to say, a photoelectric conversion device including a single crystal or polycrystalline semiconductor substrate has a thickness ten times or more the necessary thickness for photoelectric conversion and the single crystal or polycrystalline silicon substrate has not been fully used effectively. That is, most part of the single crystal silicon substrate or the polycrystalline silicon substrate only functions as a structure body that keeps the shape of a photoelectric conversion device.

With the year-by-year increase in production of photoelectric conversion devices, short of supply and resulting price increase of polycrystalline silicon, which is the material of a silicon substrate, have become problems of the industry. The production of polycrystalline silicon is expected to be about 36000 tons in 2007; in contrast, 25000 tons or more thereof is necessary for a semiconductor (LSI) and 20000 tons or more is necessary for solar cells, which means polycrystalline silicon seems to be short of supply by about 10000 tons. This short of supply is predicted to continue.

A variety of structures of photoelectric conversion devices have been disclosed. In addition to a photoelectric conversion device having a typical structure in which a single crystal silicon substrate or a polycrystalline silicon substrate is provided with an n-type or a p-type diffusion layer, a stacked photoelectric conversion device in which different kinds of unit cells are combined is known (see Patent Document 1: Examined Patent Application Publication No. H6-044638). This stacked photoelectric conversion device has a combination of a unit cell including a single crystal semiconductor and a unit cell including an amorphous semiconductor. However, this photoelectric conversion device still needs to use a single crystal semiconductor substrate or a polycrystalline semiconductor substrate.

On the other hand, development has also been advanced on photoelectric conversion devices including crystalline silicon thin films. For example, a method of manufacturing a silicon thin film solar cell is disclosed in which a crystalline silicon film is deposited over a substrate by a plasma CVD method using a VHF of 27 MHz or higher which has been pulse modulated (see Patent Document 2: Japanese Published Patent Application No. 2005-50905). Further, a technique for controlling plasma process condition to optimize dopant concentration in crystal grains and crystal grain boundaries when a polycrystalline silicon thin film is formed by a plasma CVD method over a special electrode called a texture electrode which has minute unevenness on its surface is disclosed (see Patent Document 3: Japanese Published Patent Application No. 2004-14958). However, a crystalline thin film silicon solar cell is still inferior to a single crystal silicon solar cell in crystal quality and photoelectric conversion characteristic. Moreover, a crystalline silicon film needs to be deposited to a thickness of 1 μm or more by a CVD method, which leads to a problem of low productivity.

### SUMMARY OF THE INVENTION

Conventionally, it has been difficult to produce photoelectric conversion devices enough to meet the demand while effectively utilizing limited resources. In view of such circumstances, it is an object of the present invention to provide a photoelectric conversion device with an excellent photoelectric conversion characteristic while effectively utilizing a silicon semiconductor material, and to provide a manufacturing method of the device.

Moreover, as described in Patent Document 1, the connection between unit cells is important in order to improve characteristics of the stacked photoelectric conversion device. Accordingly, it is an object of the present invention to provide a stacked photoelectric conversion device which has favorable connection between unit cells and to provide a manufacturing method of the device.

The point of the present invention lies in that a photoelectric conversion device includes a first unit cell in which a single crystal semiconductor layer with a thickness of 10 μm or less is used as a photoelectric conversion layer and a second unit cell in which a non-single-crystal semiconductor layer provided over the first unit cell is used as a photoelectric conversion layer, and an intermediate layer including a transition metal oxide is provided between the first unit cell and the second unit cell.

Another aspect of a photoelectric conversion device of the present invention includes a first unit cell and a second unit cell. In the first unit cell, one surface of a single crystal semiconductor layer is provided with a first electrode and a first impurity semiconductor layer having one conductivity type and the other surface thereof is provided with a second impurity semiconductor layer having a conductivity type opposite to the conductivity type of the first impurity semiconductor layer. In the second unit, one surface of a non-single-crystal semiconductor layer is provided with a third impurity semiconductor layer having one conductivity type and the other surface thereof is provided with a second electrode and a fourth impurity semiconductor layer having a conductivity type opposite to the conductivity type of the third impurity semiconductor layer. The first unit cell and the second unit cell are connected in series to each other with an intermediate layer interposed therebetween. The intermediate layer includes a transition metal oxide. The first electrode is provided with an insulating layer on a side opposite to the single crystal semiconductor layer and the insulating layer is bonded to a supporting substrate.

According to an aspect of a method of manufacturing a photoelectric conversion device of the present invention, a damaged layer is formed at a depth of 10 μm or less from one surface of a single crystal semiconductor substrate by introducing cluster ions through the one surface of the single crystal semiconductor substrate; a first impurity semiconductor layer, a first electrode, and an insulating layer are formed on a side of the one surface; the insulating layer is bonded to a supporting substrate; the single crystal semiconductor substrate is cleaved at the damaged layer, so that a single crystal semiconductor layer remains over the supporting substrate; a second impurity semiconductor layer is formed on a cleavage plane side of the single crystal semiconductor layer; an intermediate layer is formed over the second impurity semiconductor layer; a reactive gas including a semiconductor source gas is decomposed with an electromagnetic energy so that a third impurity semiconductor layer having one conductivity type, a non-single-crystal semiconductor layer, and a fourth impurity semiconductor layer having a conductivity type opposite to the one conductivity type are deposited in order over the intermediate layer; and a second electrode is formed over the fourth impurity semiconductor layer.

Note that single crystals are crystals whose crystal faces and crystal axes are aligned and atoms or molecules are spatially ordered. However, although single crystals are structured by orderly aligned atoms, single crystals including a lattice defect in which the alignment is disordered in part and single crystals having intended or unintended lattice distortion are also included.

In accordance with the present invention, a superficial portion of a single crystal semiconductor substrate is sliced and that portion is bonded to a supporting substrate, whereby a photoelectric conversion device in which a top cell is stacked over a bottom cell can be obtained. The bottom cell uses a single crystal semiconductor layer with a thickness of 10 μm or less as a photoelectric conversion layer, whereas the top cell uses a non-single-crystal semiconductor layer as a photoelectric conversion layer. That is to say, a photoelectric conversion device can be manufactured in which a bottom cell using a single crystal semiconductor layer as a photoelectric conversion layer and a top cell using a non-single-crystal semiconductor layer as a photoelectric conversion layer, which is stacked over the bottom cell, are provided over a large-area glass substrate which can resist temperatures of 700° C. or lower. The single crystal semiconductor layer is obtained by separation of the superficial portion of the single crystal semiconductor substrate. Since the single crystal semiconductor substrate can therefore be reused, resources can be effectively used.

Moreover, in accordance with the present invention, the first unit cell and the second unit cell are connected to each other with the intermediate layer including a transition metal oxide interposed therebetween; therefore, carrier recombination between the first unit cell and the second unit cell is effectively performed. Accordingly, the internal electromotive force effect between the first unit cell and the second unit cell can be decreased.

### BRIEF DESCRIPTION OF THE DRAWINGS

FIG. 1 is a plan view showing a structure of a tandem photoelectric conversion device.

FIG. 2 is a cross-sectional view showing the structure of the tandem photoelectric conversion device.

FIG. 3 shows an example of an energy band diagram of the tandem photoelectric conversion device.

FIG. 4 is a cross-sectional view showing a structure of a stacked photoelectric conversion device.

FIG. 5 shows an example of an energy band diagram of a tandem photoelectric conversion device.

FIG. 6 shows an example of an energy band diagram of a tandem photoelectric conversion device.

FIG. 7 shows an example of an energy band diagram of a tandem photoelectric conversion device.

FIGS. 8A to 8D are cross-sectional views showing a process for manufacturing the stacked photoelectric conversion device.

FIGS. 9A and 9B are cross-sectional views showing a process for manufacturing the stacked photoelectric conversion device.

FIGS. 10A to 10C are cross-sectional views showing a process for manufacturing the stacked photoelectric conversion device.

FIGS. 11A to 11C are cross-sectional views showing a process for manufacturing the stacked photoelectric conversion device.

FIG. 12 is a cross-sectional view showing a process for manufacturing the stacked photoelectric conversion device.

FIG. 13 is a schematic view showing a structure of an ion doping apparatus.

FIG. 14 is a schematic view showing a structure of a laser processing apparatus.

FIGS. 15A to 15C are cross-sectional views showing a process for manufacturing the stacked photoelectric conversion device.

FIGS. 16A to 16C are cross-sectional views showing a process for manufacturing the stacked photoelectric conversion device.

FIGS. 17A to 17C are cross-sectional views showing a process for manufacturing the stacked photoelectric conversion device.

FIGS. 18A to 18C are cross-sectional views showing a process for manufacturing the stacked photoelectric conversion device.

FIGS. 19A to 19C are cross-sectional views showing a process for manufacturing the stacked photoelectric conversion device.

FIGS. 20A and 20B are a plan view and a cross-sectional view showing a structure of a photovoltaic power generation module.

FIG. 21 shows an example of a photovoltaic power generation system.

### DETAILED DESCRIPTION OF THE INVENTION

Embodiment modes of the present invention are hereinafter described in detail with reference to the drawings. The present invention is not limited to the following description, and it is easily understood by those skilled in the art that modes and details thereof can be modified in various ways without departing from the purpose and the scope of the present invention. Therefore, the present invention should not be construed as being limited to the description of the following embodiment modes. Note that in the structures of the present invention, the same portions are denoted by the same reference numerals through the drawings.

### Embodiment Mode 1

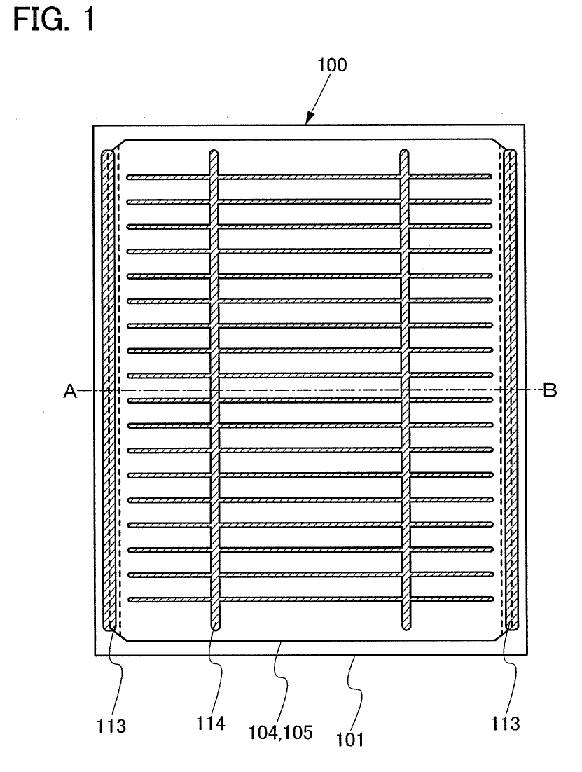

FIG. 1 is a plan view of a photoelectric conversion device 100 of this embodiment mode. This photoelectric conversion device 100 includes a first unit cell 104 and a second unit cell 105 which are fixed to a supporting substrate 101. The first unit cell 104 and the second unit cell 105 include semiconductor junction by which photoelectric conversion is performed.

The first unit cell 104 is provided with a first electrode 103 on the supporting substrate 101 side and the second unit cell 105 is provided with a second electrode 112 on a surface side of the second unit cell 105. The first electrode 103 is connected to a first auxiliary electrode 113 and a second auxiliary electrode 114 is provided over the second electrode 112. The photoelectric conversion device 100 of this embodiment mode has a structure in which the first unit cell 104 and the second unit cell 105 are stacked over the supporting substrate 101 having an insulating surface; therefore, positive and negative electrodes are exposed to the same surface side of the supporting substrate 101.

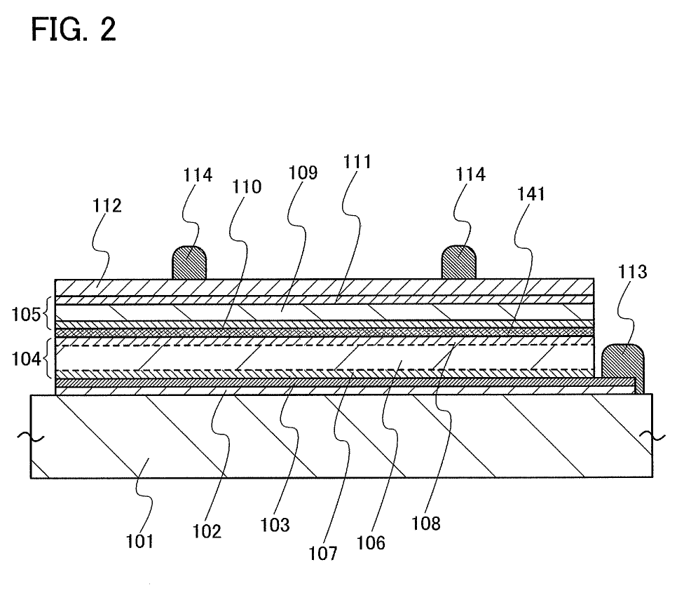

A cross-sectional structure of the photoelectric conversion device along section line A-B of FIG. 1 is shown in FIG. 2. FIG. 2 illustrates a so-called tandem photoelectric conversion device in which the first unit cell 104 and the second unit cell 105 are stacked over the supporting substrate 101. The supporting substrate 101 is a substrate having an insulating surface or an insulating substrate, and any of a variety of glass substrates that are used in the electronics industry, such as aluminosilicate glass substrates, aluminoborosilicate glass substrates, and barium borosilicate glass substrates, can be used.

An insulating layer 102 is provided between the supporting substrate 101 and the first unit cell 104. The first electrode 103 is provided between the first unit cell 104 and the insulating layer 102 and the second electrode 112 is provided over the second unit cell 105. The insulating layer 102 is bonded to the supporting substrate 101 and further disposed in close contact with the first electrode 103, whereby the first unit cell 104 and the second unit cell 105 are fixed to the supporting substrate 101. As the insulating layer 102, an insulating film having a smooth and hydrophilic surface is used in order to be bonded to the supporting substrate 101.

Single crystal silicon is typically used for a single crystal semiconductor layer 106 of the first unit cell 104. A polycrystalline semiconductor (typically polycrystalline silicon) layer can be used instead of the single crystal semiconductor layer. A first impurity semiconductor layer 107 having one conductivity type and a second impurity semiconductor layer 108 having a conductivity type opposite to the one conductivity type are manufactured by adding a predetermined impurity to the single crystal semiconductor layer 106. If the first impurity semiconductor layer 107 has p-type conductivity, the second impurity semiconductor layer 108 has n-type conductivity; the opposite is also possible. As the p-type impurity, an element belonging to Group 13 in the periodic table, such as boron, is applied; as the n-type impurity, an element belonging to Group 15 in the periodic table, such as phosphorus or arsenic, is applied. The impurity element can be added by ion implantation or ion doping. In this specification, ion implantation indicates a method by which an ionized gas after mass separation is introduced to a semiconductor, and ion doping indicates a method by which an ionized gas without mass separation is introduced to a semiconductor.

The single crystal semiconductor layer 106 is obtained by slicing a single crystal semiconductor substrate. For example, the single crystal semiconductor layer 106 is formed by a hydrogen ion implantation separation method in such a manner that hydrogen ions are implanted into a single crystal semiconductor substrate at a predetermined depth at high concentration and then heat treatment is performed to separate a single crystal silicon layer at a superficial portion of the single crystal semiconductor substrate. In another method for obtaining the single crystal semiconductor layer 106, a single crystal semiconductor is epitaxially grown on porous silicon and a porous silicon layer is separated by cleavage by water-jetting. As the single crystal semiconductor substrate, a single crystal silicon wafer is typically employed. The thickness of the single crystal semiconductor layer 106 is 0.1 μm or more and 10 μm or less, preferably 1 μm or more and 5 μm or less. In the case of using a single crystal silicon semiconductor for the single crystal semiconductor layer 106, since a single crystal silicon semiconductor has an energy gap of 1.12 eV and is of indirect transition type, the single crystal semiconductor layer 106 needs to have thickness of the above range to absorb sunlight.

The single crystal semiconductor layer 106 may alternatively be formed in such a manner that an amorphous semiconductor layer is formed over a layer sliced from a single crystal semiconductor substrate and the amorphous semiconductor layer is crystallized by laser irradiation or heat treatment. In accordance with this method, the thickness of the single crystal semiconductor layer 106 can be easily increased.

The first unit cell and the second unit cell are connected in series to each other with an intermediate layer interposed therebetween. In the photoelectric conversion device of the present invention, an intermediate layer 141 includes a transition metal oxide. Among the transition metal oxides, an oxide of a metal belonging to any of Groups 4 to 8 in the periodic table is preferably used. In particular, vanadium oxide, niobium oxide, tantalum oxide, chromium oxide, molybdenum oxide, tungsten oxide, manganese oxide, and rhenium oxide are preferable because of a high electron accepting property. Among these oxides, molybdenum oxide is especially preferable since molybdenum oxide is stable in the air and its hygroscopic property is low so that molybdenum oxide can be easily treated.

The intermediate layer preferably has a high light-transmitting property. The photoelectric conversion device of this embodiment mode has a structure in which light enters from the second electrode 112 side; therefore, the light entered from the second electrode 112 side is absorbed in the second unit cell 105 and light which is not absorbed in the second unit cell 105 passes through the intermediate layer 141 and is absorbed in the first unit cell 104. For this reason, the intermediate layer 141 preferably has high transmittance to light particularly with wavelengths that are absorbed in the first unit cell 104.

The thickness of the intermediate layer 141 is preferably 1 nm or more and 50 nm or less.

A variety of methods can be used for forming the intermediate layer, whether the method is a dry process or a wet process. In addition, each layer may be formed by a different method. A vacuum evaporation method, a sputtering method, or the like can be employed as the dry process, for example. In an example of the wet process, a composition is adjusted by a sol-gel method using metal alkoxide and an inkjet method, a spin coating method, or the like is used to form a film.

For a non-single-crystal semiconductor layer 109 of the second unit cell 105, amorphous silicon is typically applied. A microcrystal semiconductor (typically microcrystal silicon) layer can be used instead of the amorphous semiconductor layer. The third impurity semiconductor layer 110 having one conductivity type and the fourth impurity semiconductor layer 111 having a conductivity type opposite to the one conductivity type are each formed using an amorphous semiconductor layer or a microcrystal semiconductor layer including a predetermined impurity. Typically, amorphous silicon or microcrystal silicon is used, and amorphous silicon carbide can alternatively be used. If the third impurity semiconductor layer 110 has p-type conductivity, the fourth impurity semiconductor layer 111 has n-type conductivity; the opposite is also possible.

The non-single-crystal semiconductor layer 109 is formed by decomposing a reactive gas including a semiconductor source gas with use of an electromagnetic energy. As the semiconductor source gas, a silicon hydride typified by silane or disilane, a silicon fluoride, or a silicon chloride is used. Such a semiconductor source gas or another semiconductor source gas including hydrogen or an inert gas is used as the reactive gas. The non-single-crystal semiconductor layer 109 is formed by a plasma CVD apparatus using this reactive gas in such a manner that a high-frequency electric power of 10 MHz to 200 MHz is applied as the electromagnetic energy. As the electromagnetic energy, a microwave electric power of 1 GHz to 5 GHz, typically 2.45 GHz may be applied instead of the high-frequency electric power. The third impurity semiconductor layer 110 and the fourth impurity semiconductor layer 111 are formed similarly by a plasma CVD apparatus in such a manner that diborane is added as the impurity to the reactive gas in the case of giving p-type conductivity and phosphine is added as the impurity to the reactive gas in the case of giving n-type conductivity. For the non-single-crystal semiconductor layer 109, typically, an amorphous silicon layer is employed. The thickness of the non-single-crystal semiconductor layer 109 is 50 nm or more and 300 nm or less, preferably 100 nm or more and 200 nm or less. In the case of using an amorphous silicon semiconductor with an energy gap of 1.75 eV for the non-single-crystal semiconductor layer 109, the thickness of the above range allows the non-single-crystal semiconductor layer 109 to absorb light with shorter wavelengths than 600 nm and to convert the light into electricity.

As the non-single-crystal semiconductor layer 109 of the second unit cell 105, a microcrystal semiconductor layer (typically a microcrystal silicon layer) can be used. SiH₄ is a typical semiconductor source gas used for forming the microcrystal semiconductor layer, and Si₂H₆ can alternatively be used. Further alternatively, SiH₂Cl₂, SiHCl₃, SiCl₄, SiF₄, or the like may be mixed to SiH₄ as appropriate. The microcrystal semiconductor layer is formed by a plasma CVD method using this semiconductor source gas diluted with hydrogen; fluorine; hydrogen and one or more of helium, argon, krypton, and neon; or fluorine and one or more of helium, argon, krypton, and neon. The dilution ratio is preferably 10 times to 3000 times. The film formation is performed using glow discharge plasma generated under reduced pressure of about 0.1 Pa to 133 Pa. The electric power for generating plasma may be high-frequency electric power of HF band or VHF band of 10 MHz to 200 MHz or a microwave electric power of 1 GHz to 5 GHz. Moreover, a carbide gas such as CH₄ or C₂H₆ or a germanium gas such as GeH₄ or GeF₄ may be mixed into the semiconductor source gas so that the energy band width is adjusted to 1.5 eV to 2.4 eV or 0.9 eV to 1.1 eV. The microcrystal semiconductor layer has lattice distortion which changes the optical characteristics from indirect transition type of single crystal silicon into direct transition type. The lattice distortion of at least 10% causes the optical characteristics to change into direct transition type; however, the local distortion makes the optical characteristics in which direct transition and indirect transition are mixed. The microcrystal semiconductor layer has an energy gap of about 1.45 eV which is larger than that of single crystal silicon; therefore, light with shorter wavelengths than 600 nm can be absorbed and converted into electricity.

The photoelectric conversion device of this embodiment mode has a structure in which light enters from the second electrode 112 side. The second electrode 112 is formed using a transparent electrode material such as indium tin oxide, tin oxide, or zinc oxide. The first electrode 103 is formed of a metal material selected from titanium, molybdenum, tungsten, tantalum, chromium, and nickel. The first electrode 103 includes a layer of a nitride of titanium, molybdenum, tungsten, or tantalum, and the layer of the nitride thereof is in contact with the first impurity semiconductor layer 107. With the provision of the metal nitride between the semiconductor layer and the metal layer, the layers can have closer contact with each other.

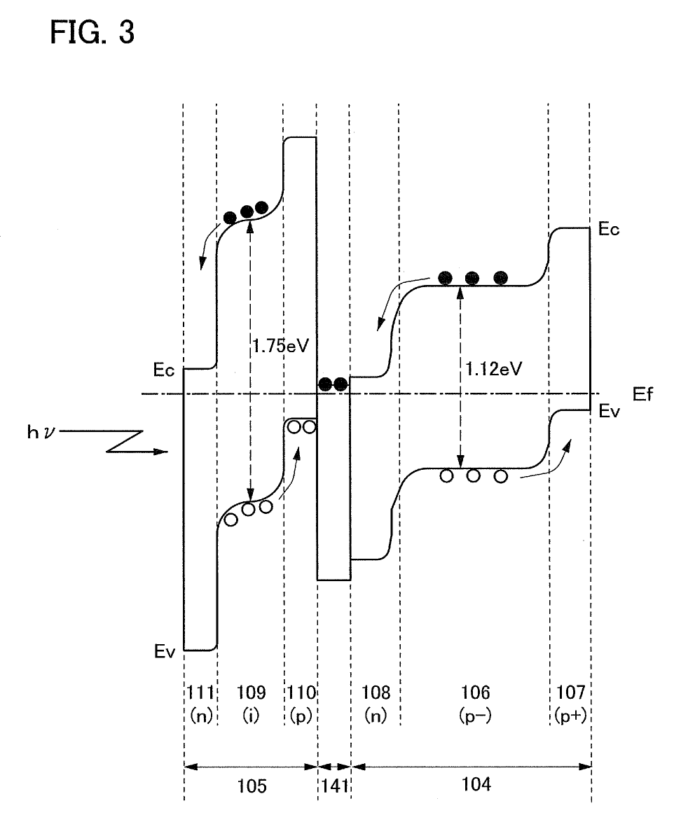

FIG. 3 is an energy band diagram when the first unit cell 104 includes the single crystal semiconductor layer 106 with an energy gap of 1.12 eV and the second unit cell 105 includes the non-single-crystal semiconductor layer 109 with an energy gap of 1.75 eV. The second unit cell 105 including the non-single-crystal semiconductor layer 109 with large energy gap is provided on the light incidence side and the first unit cell 104 including the single crystal semiconductor layer 106 with small energy gap is provided behind the second unit cell 105. Note that the first impurity semiconductor layer 107 and the third impurity semiconductor layer 110 are each an p-type semiconductor and the second impurity semiconductor layer 108 and the fourth impurity semiconductor layer 111 are each an n-type semiconductor in this case.

As shown in the band diagram of FIG. 3, electrons excited by light absorption flow to the n-type semiconductor and holes flow to the p-type semiconductor. If the intermediate layer 141 is not provided, p-n junction is formed at the connection portion of the first unit cell 104 and the second unit cell 105 and a diode is inserted in a direction opposite to a direction of current flow in an equivalent circuit. That is to say, the internal electromotive force effect is generated. Since the intermediate layer 141 shown in this embodiment mode includes a transition metal oxide, electrons can flow therethrough. Thus, electrons can be effectively injected from the first unit cell 104 to the intermediate layer 141, as shown in FIG. 3. Then, recombination with holes existing near the interface between the third impurity semiconductor layer 110 and the intermediate layer 141 can be effectively performed. Accordingly, recombination current can flow between the first unit cell 104 and the second unit cell 105 by an operation of this intermediate layer 141. That is to say, the internal electromotive force effect caused by direct bonding of the second impurity semiconductor layer 108 and the third impurity semiconductor layer 110 can be eliminated, whereby the conversion efficiency of the tandem photoelectric conversion device can be increased.

In the tandem photoelectric conversion device of FIG. 2, the first unit cell 104 formed using the single crystal semiconductor layer is used as the bottom cell; therefore, light with wavelengths of 800 nm or longer can be absorbed and converted into electricity, which contributes to improvement of photoelectric conversion efficiency. In this case, the single crystal semiconductor layer 106 is thinned to have a thickness of 10 μm or less, so that loss due to recombination of photogenerated carriers can be decreased.

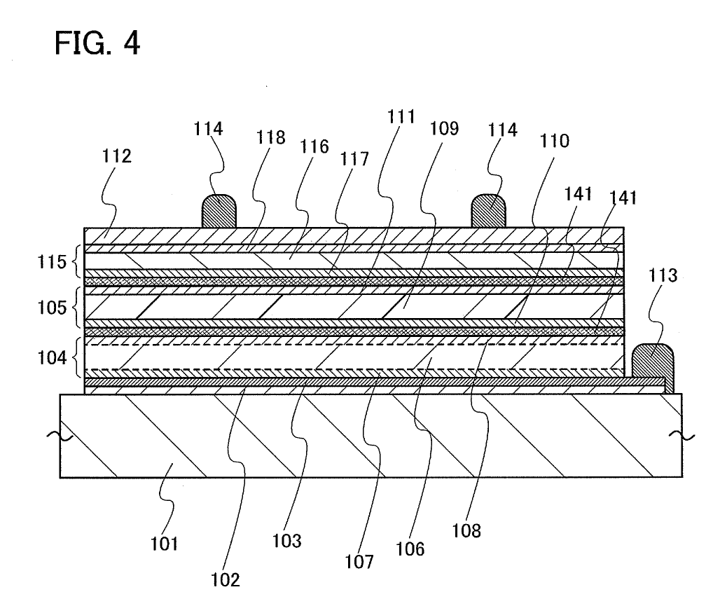

FIG. 4 shows an example of a stacked photoelectric conversion device in which three unit cells are stacked. The first unit cell 104 provided over the supporting substrate 101 uses the single crystal semiconductor layer 106 as a photoelectric conversion layer, the second unit cell 105 provided over the first unit cell 104 uses the non-single-crystal semiconductor layer 109 as a photoelectric conversion layer, and a third unit cell 115 provided over the second unit cell 105 uses a non-single-crystal semiconductor layer 116 as a photoelectric conversion layer. The unit cells are connected in series with the intermediate layer interposed therebetween.

In this case, the single crystal semiconductor layer 106 has an energy gap of 1.12 eV; therefore, the non-single-crystal semiconductor layer 109 of the second unit cell 105 and the non-single-crystal semiconductor layer 116 of the third unit cell 115 which are located closer to the light incidence side than the first unit cell 104 preferably have an energy gap of 1.45 eV to 1.65 eV and an energy gap of 1.7 eV to 2.0 eV, respectively. Sunlight can be effectively absorbed when each unit cell absorbs light with a different wavelength region.

In order for the non-single-crystal semiconductor layer 109 of the second unit cell 105 to have an energy gap of 1.45 eV to 1.65 eV, amorphous silicon germanium or microcrystal silicon is used. In order for the non-single-crystal semiconductor layer 116 of the third unit cell 115 to have an energy gap of 1.7 eV to 2.0 eV, amorphous silicon (1.75 eV) or amorphous silicon carbide (1.8 eV to 2.0 eV) is used.

In FIG. 4, a fifth impurity semiconductor layer 117 is similar to the third impurity semiconductor layer 110 and a sixth impurity semiconductor layer 118 is similar to the fourth impurity semiconductor layer 111; therefore the detailed description is not made.

### Embodiment Mode 2

This embodiment mode describes an intermediate layer with a structure different from the intermediate layer described in Embodiment Mode 1.

For the intermediate layer 141 in FIG. 2, a composite material of a transition metal oxide and an organic compound can be used. Note that in this specification, the composite refers to not just a simple mixture of two materials but a mixture of a plurality of materials so that an electric charge can be transported among the materials.

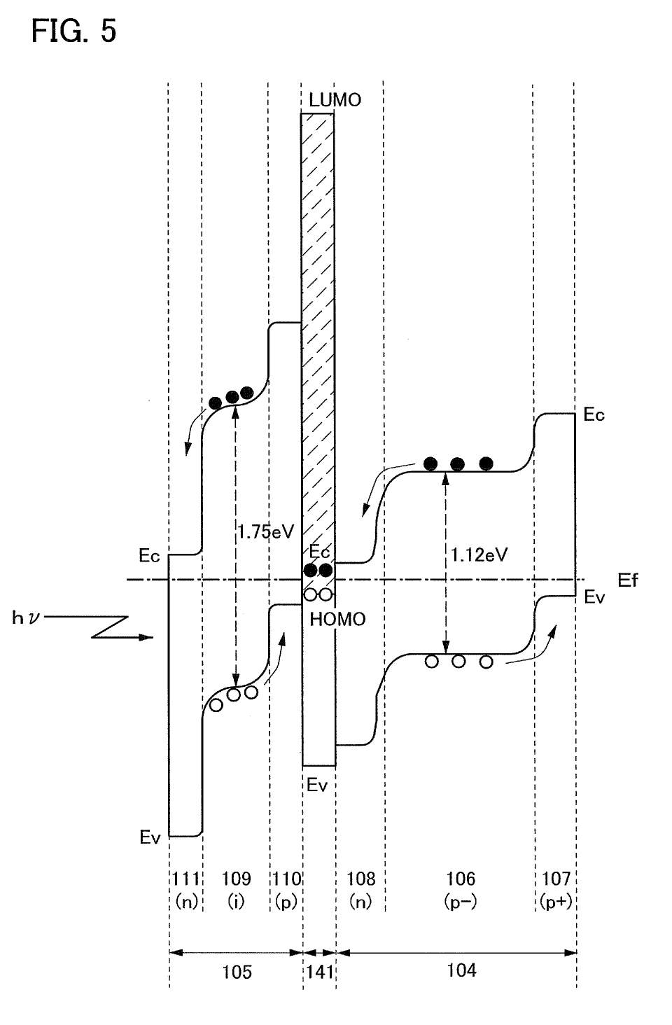

Since a composite material including a transition metal oxide and an organic compound has high carrier density, the composite material can favorably be used for a recombination center. FIG. 5 is an energy band diagram when a composite material of a transition metal oxide and an organic compound is used for the intermediate layer 141. In the intermediate layer 141 shown in this embodiment mode, an electron at the HOMO (highest occupied molecular orbital) level of the organic compound is transferred to a conduction band of the transition metal oxide, whereby interaction occurs between the transition metal oxide and the organic compound. Due to this interaction, the carrier density of the composite material including the transition metal oxide and the organic compound is high and ohmic contact with an adjacent layer is possible. Accordingly, by the use of this composite material for the intermediate layer, carrier recombination can be carried out without an energy barrier at the interface of the layers. Thus, the internal electromotive force effect can be decreased and high photoelectric conversion efficiency can be achieved.

As shown in FIG. 5, since the composite material of this embodiment mode uses the organic compound with large band gap, diffusion of electrons generated in the non-single-crystal semiconductor layer 109 to the first unit cell 104 can be suppressed.

As the transition metal oxide that can be used for the intermediate layer 141, the transition metal oxide shown in Embodiment Mode 1 can be given. In specific, among the transition metal oxides, an oxide of a metal belonging to any of Groups 4 to 8 in the periodic table is preferably used. In particular, vanadium oxide, niobium oxide, tantalum oxide, chromium oxide, molybdenum oxide, tungsten oxide, manganese oxide, and rhenium oxide are preferable because of a high electron accepting property. Among these, molybdenum oxide is especially preferable since molybdenum oxide is stable in the air and its hygroscopic property is low so that molybdenum oxide can be easily treated.

As the organic compound that can be used for the intermediate layer 141, a variety of compounds such as an aromatic amine compound, a carbazole derivative, an aromatic hydrocarbon, and a macromolecular compound (oligomer, dendrimer, polymer, or the like) can be used. The organic compound of the composite material is preferably an organic compound having a high hole transporting property. Specifically, a material having a hole mobility of 10⁻⁶ cm²/Vs or higher is preferably used. Any other material can alternatively be used as long as the material has a hole transporting property that is higher than an electron transporting property. The organic compounds that can be used for the composite material are specifically given below.

As the aromatic amine compounds that can be used for the composite material, the following can be given as examples: 4,4′-bis[N-(1-naphthyl)-N-phenylamino]biphenyl (abbreviation: NPB); N,N′-bis(3-methylphenyl)-N,N′-diphenyl-[1,1′-biphenyl]-4,4′-diamine (abbreviation: TPD); 4,4′,4″-tris(N,N-diphenylamino)triphenylamine (abbreviation: TDATA); 4,4′,4″-tris[N-(3-methylphenyl)-N-phenylamino]triphenylamine (abbreviation: MTDATA); N,N′-bis(spiro-9,9′-bifluoren-2-yl)-N,N′-diphenylbenzidine (abbreviation: BSPB); N,N-bis(4-methylphenyl)-N,N-diphenyl-p-phenylenediamine (abbreviation: DTDPPA); 4,4′-bis[N-(4-diphenylaminophenyl)-N-phenylamino]biphenyl (abbreviation: DPAB); N,N′-bis[4-[bis(3-methylphenyl)amino]phenyl]-N,N′-diphenyl-[1,1′-Biphenyl]-4,4′-diamine (abbreviation: DNTPD); 1,3,5-tris[N-(4-diphenylaminophenyl)-N-phenylamino]benzene (abbreviation: DPA3B); or the like.

As the carbazole derivative that can be used for the composite material, the following can be given specifically: 3-[N-(9-phenylcarbazol-3-yl)-N-phenylamino]-9-phenylcarbazole (abbreviation: PCzPCA1); 3,6-bis[N-(9-phenylcarbazol-3-yl)-N-phenylamino]-9-phenylcarbazole (abbreviation: PCzPCA2); or 3-[N-(1-naphthyl)-N-(9-phenylcarbazol-3-yl)amino]-9-phenylcarbazole (abbreviation: PCzPCN1).

As the carbazole derivative that can be used for the composite material, the following can be given: 4,4′-di(N-carbazolyl)biphenyl (abbreviation: CBP); 1,3,5-tris[4-(N-carbazolyl)phenyl]benzene (abbreviation: TCPB); 9-[4-(N-carbazolyl)phenyl]-10-phenylanthracene (abbreviation: CzPA); 1,4-bis[4-(N-carbazolyl)phenyl]-2,3,5,6-tetraphenylbenzene; or the like.

As the aromatic hydrocarbon that can be used for the composite material, the following can be given as examples: 2-tert-butyl-9,10-di(2-naphthyl)anthracene (abbreviation: t-BuDNA); 2-tert-butyl-9,10-di(1-naphthyl)anthracene; 9,10-bis(3,5-diphenylphenyl)anthracene (abbreviation: DPPA); 2-tert-butyl-9,10-bis(4-phenylphenyl)anthracene (abbreviation: t-BuDBA); 9,10-di(2-naphthyl)anthracene (abbreviation: DNA); 9,10-diphenylanthracene (abbreviation: DPAnth); 2-tert-butylanthracene (abbreviation: t-BuAnth); 9,10-bis(4-methyl-1-naphthyl)anthracene (abbreviation: DMNA); 9,10-bis[2-(1-naphthyl)phenyl]-2-tert-butyl-anthracene; 9, 10-bis[2-(1-naphthyl)phenyl]anthracene; 2,3,6,7-tetramethyl-9,10-di(1-naphthyl)anthracene; 2,3,6,7-tetramethyl-9,10-di(2-naphthyl)anthracene; 9,9′-bianthryl; 10,10′-diphenyl-9,9′-bianthryl; 10,10′-bis(2-phenylphenyl)-9,9′-bianthryl; 10,10′-bis[(2,3,4,5,6-pentaphenyl)phenyl]-9,9′-bianthryl; anthracene; tetracene; rubrene; perylene; 2,5,8,11-tetra(tert-butyl)perylene; and the like. Other than those above, pentacene, coronene, or the like can be used. In this manner, it is more preferable to use an aromatic hydrocarbon having hole mobility of 1×10⁻⁶ cm²/Vs or more and having 14 to 42 carbon atoms.

The aromatic hydrocarbon that can be used for the composite material may have a vinyl skeleton. As the aromatic hydrocarbon having a vinyl skeleton, the following can be given for example: 4,4′-bis(2,2-diphenylvinyl)biphenyl (abbreviation: DPVBi); 9,10-bis[4-(2,2-diphenylvinyl)phenyl]anthracene (abbreviation: DPVPA); and the like.

Moreover, a macromolecular compound such as poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′phenylamino}phenyl) methacrylamide] (abbreviation: PTPDMA), or poly[N,N′-bis(4-butylphenyl)-N,N′-bis(phenyl)benzidine] (abbreviation: Poly-TPD) can also be used as the organic compound that can be used for the composite material.

Above all, an organic compound without an amine skeleton (such as a carbazole derivative or an aromatic hydrocarbon) is preferably used from the aspect of light transmittance. The composite material including the organic compound without an amine skeleton has high transmittance of light with wavelengths (800 nm or longer) absorbed by the single crystal semiconductor used for the bottom cell. Therefore, by the use of the organic compound without an amine skeleton (for example, a carbazole derivative or an aromatic hydrocarbon), higher photoelectric conversion efficiency can be achieved.

The aforementioned intermediate layer preferably has a thickness of 1 nm or more and 50 nm or less. Since the intermediate layer shown in this embodiment mode has high carrier density and an excellent light-transmitting property, the thickness can be larger than that of an intermediate layer formed of another material.

A variety of methods can be used for forming the intermediate layer, whether the method is a dry process or a wet process. In addition, each layer may be formed by a different method. As the dry process, for example, a co-evaporation method by which a plurality of evaporation materials is vaporized from a plurality of evaporation sources to form a film, or the like is given. In an example of the wet process, a composition including a composite material is adjusted by a sol-gel method and an inkjet method, a spin coating method, or the like is used to form a film.

### Embodiment Mode 3

This embodiment mode describes an intermediate layer with a structure in which a layer including the transition metal oxide as shown in Embodiment Mode 1 and a layer including a composite material of a transition metal oxide and an organic compound are stacked.

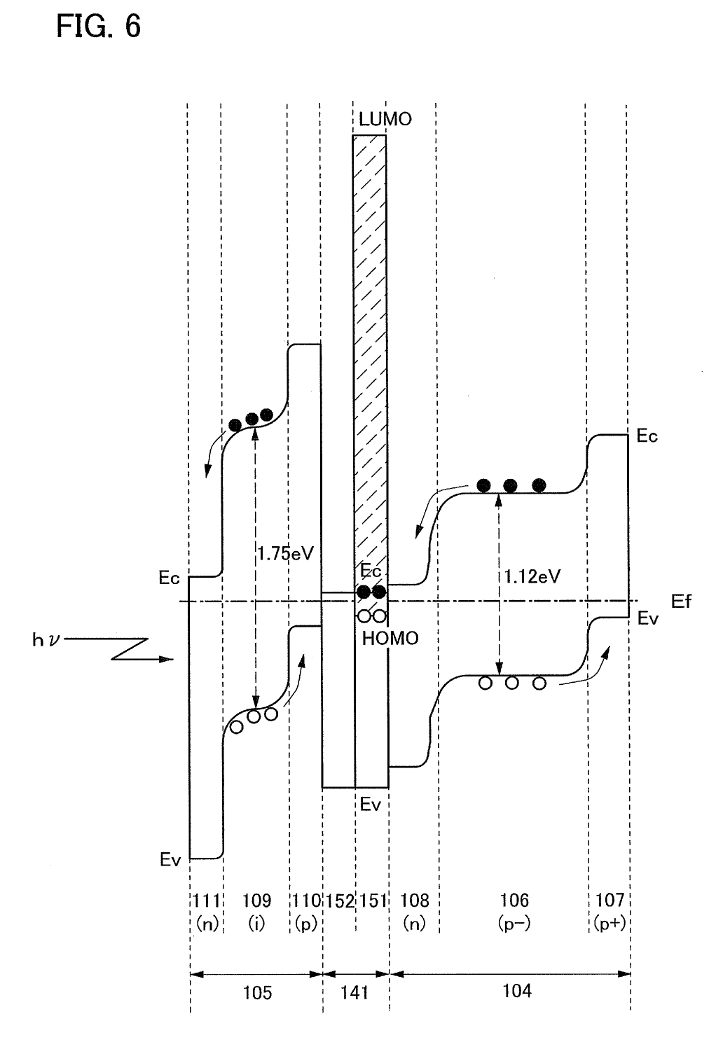

FIG. 6 is an energy band diagram of the intermediate layer 141 with a structure in which a layer 151 including a composite material of a transition metal oxide and an organic compound and a layer 152 including a transition metal oxide are stacked over the first unit cell 104. The structure shown in FIG. 6 makes it possible to prevent the layer 151 including the composite material from being damaged at the time of forming the second unit cell 105.

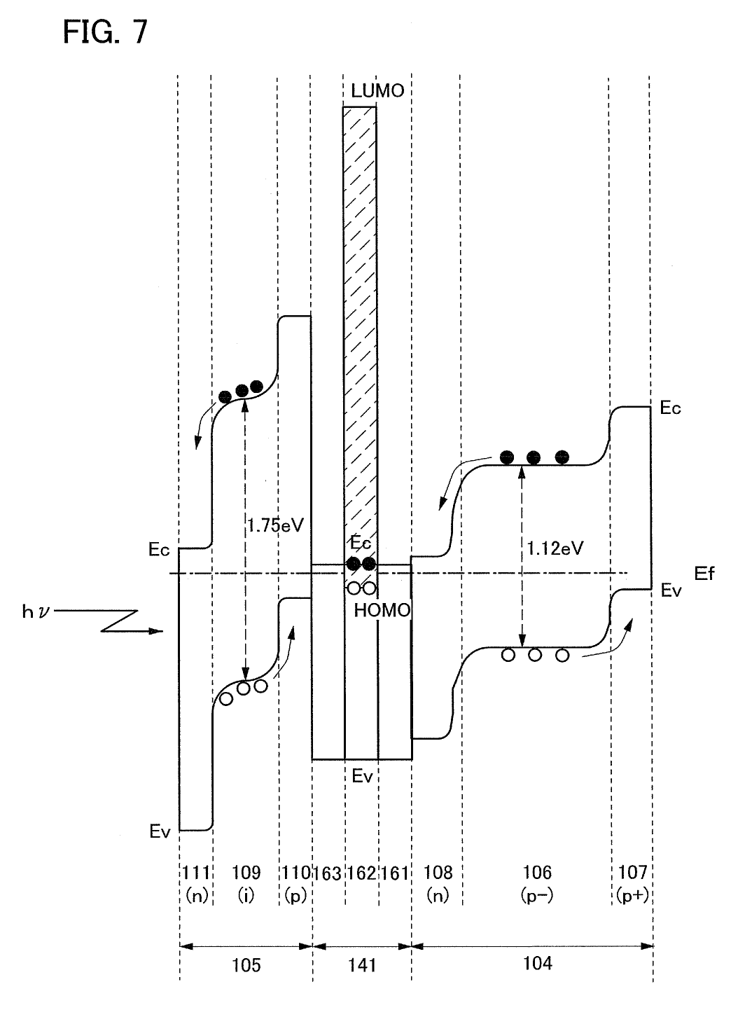

As an alternative to the above structure, a plurality of layers each including a transition metal oxide and a plurality of layers each including a composite material may be used to form the intermediate layer. Even in this case, it is preferable to provide the layer including a transition metal oxide over the layer including a composite material so that the layer including a composite material is prevented from being damaged. FIG. 7 is an energy band diagram of the intermediate layer 141 with a structure in which a layer 161 including a transition metal oxide, a layer 162 including a composite material of a transition metal oxide and an organic compound, and a layer 163 including a transition metal oxide are stacked over the first unit cell 104. As shown in FIG. 7, even the intermediate layer with the three-layer structure functions as a recombination center. By the function of this intermediate layer 141, recombination current can flow between the first unit cell 104 and the second unit cell 105. That is to say, the internal electromotive force effect caused by direct bonding of the second impurity semiconductor layer 108 and the third impurity semiconductor layer 110 can be eliminated, whereby the conversion efficiency of the tandem photoelectric conversion device can be increased.

### Embodiment Mode 4

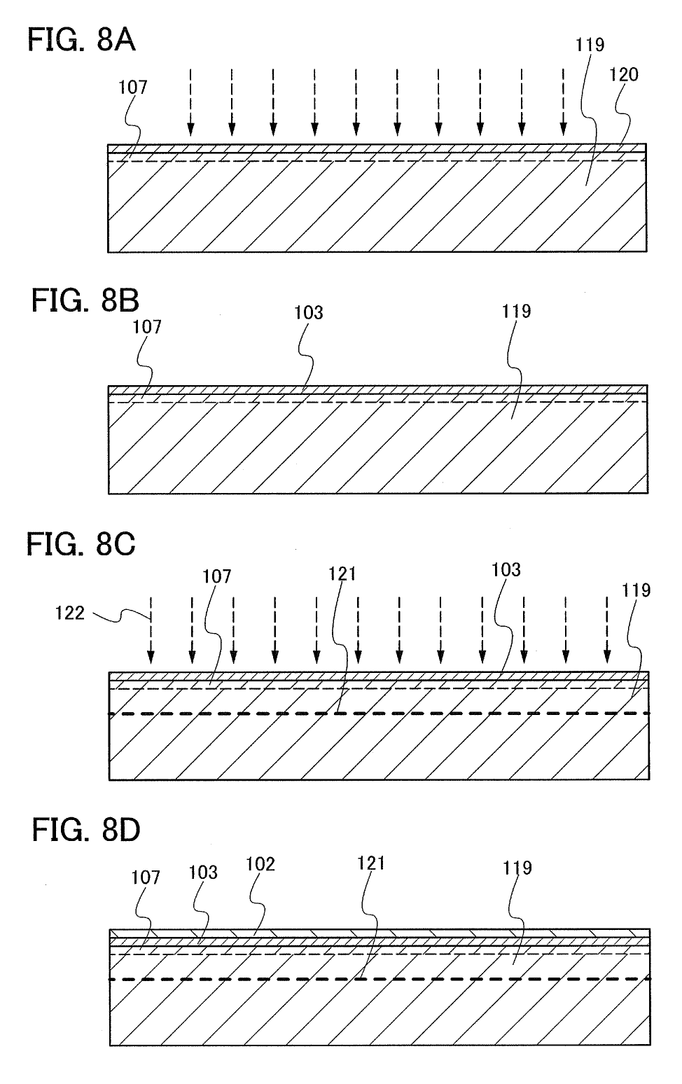

This embodiment mode describes a method of manufacturing the photoelectric conversion device 100 with its cross-sectional structure along section line A-B of FIG. 1 corresponding to the structure shown in FIG. 2. A semiconductor substrate 119 shown in FIG. 8A is a substrate with an approximately rectangular shape cut out from a circular single crystal semiconductor substrate. Needless to say, the shape of a top surface of the semiconductor substrate 119 is not limited in particular; however, the semiconductor substrate 119 preferably has an approximately rectangular shape in the case where a supporting substrate which supports a single crystal semiconductor layer is rectangular in shape. The semiconductor substrate 119 is typically a single crystal silicon substrate and preferably has its surface polished to have a mirror surface. This is for the purpose of disposing the semiconductor substrate 119 in close contact with the supporting substrate with an insulating layer for bonding interposed therebetween. For example, a p-type single crystal silicon wafer with a resistivity of about 1 Ωcm to 10 Ωcm is used as the semiconductor substrate 119. The shape of the top surface of the semiconductor substrate 119 is preferably approximately rectangular as described above.

A protection film 120 is preferably formed of silicon oxide or silicon nitride by a chemical vapor deposition method typified by a plasma CVD method. The protection film 120 is preferably provided in order to prevent the surface of the semiconductor substrate 119 from losing its flatness due to irradiation with ions at the time of forming a damaged layer or an impurity semiconductor layer in the semiconductor substrate 119. The protection film 120 is preferably provided to a thickness of 50 nm to 200 nm.

Next, the first impurity semiconductor layer 107 having one conductivity type is formed in the semiconductor substrate 119. For example, the first impurity semiconductor layer 107 is formed to have p-type conductivity by adding boron as the impurity imparting one conductivity type. In the photoelectric conversion device of this embodiment mode, the first impurity semiconductor layer 107 is disposed on the side opposite to the light incidence side so that a back surface field (BSF) is formed. Boron is preferably added using an ion doping apparatus by which the substrate is irradiated with ions which are accelerated by an electric field without mass separation with B₂H₆ or BF₃ used as a source gas. This is because, even when the area of the semiconductor substrate 119 is more than 300 mm diagonally, the area to be irradiated with the ion beam can be enlarged to perform the process effectively. For example, a linear ion beam with a length of more than 300 mm on a long side is formed and delivered from one end to the other end of the semiconductor substrate 119. Thus, the first impurity semiconductor layer 107 can be homogeneously formed over the entire surface of the semiconductor substrate 119.

In FIG. 8B, the protection film 120 is removed and the first electrode 103 is formed over the first impurity semiconductor layer 107. The first electrode 103 is preferably formed of heat-resistant metal. As the heat-resistant metal, a metal material such as titanium, molybdenum, tungsten, tantalum, chromium, or nickel is used. A nitride of any of these metal materials may be formed in contact with the first impurity semiconductor layer 107 so that the first electrode 103 is formed to have a stacked-layer structure. By the formation of the nitride of metal, the first electrode 103 and the first impurity semiconductor layer 107 can have closer contact with each other. The first electrode 103 is formed by a vacuum evaporation method or a sputtering method.

FIG. 8C shows a step of forming a damaged layer 121 by irradiating the surface of the semiconductor substrate 119, which is provided with the first electrode 103, with an ion beam 122 including hydrogen ions. As the hydrogen ions, preferably cluster ions typified by H₃⁺ are introduced to form the damaged layer 121 in a region at a certain depth from the surface. The depth at which the damaged layer 121 is formed depends on the acceleration energy of the ions. The thickness of the single crystal semiconductor layer to be obtained from the semiconductor substrate 119 is determined depending on the depth of the damaged layer 121; therefore, the electric field intensity for accelerating the cluster ions is determined in consideration of the thickness of the single crystal semiconductor layer. The damaged layer 121 is preferably formed to a depth of less than 10 μm, that is, 50 nm or more and less than 10000 nm, preferably 100 nm to 5000 nm from the surface of the semiconductor substrate 119. By introducing the cluster ions to the semiconductor substrate 119 through the first electrode 103, it is possible to prevent the surface from being damaged due to the ion irradiation.

The hydrogen cluster ions typified by H₃⁺ can be introduced using an ion doping apparatus in such a manner that hydrogen plasma is generated and ions generated in the plasma are accelerated by an electric field without mass separation. By the use of the ion doping apparatus, the process can be easily performed even on the semiconductor substrate 119 with a large area.

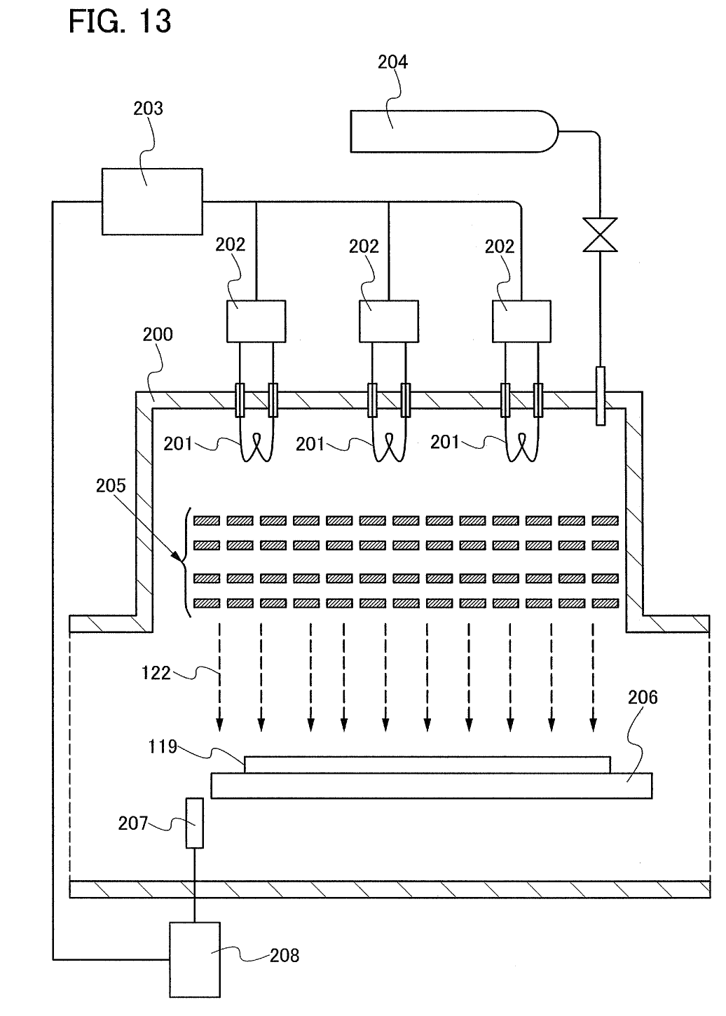

FIG. 13 is a schematic view showing a structure of an ion doping apparatus by which a plurality of kinds of ions generated from an ion source 200 is introduced to the semiconductor substrate 119 without mass separation. A predetermined gas such as hydrogen is supplied from a gas supplying portion 204 to the ion source 200. The ion source 200 is provided with filaments 201. A filament power source 202 applies ark discharge voltage to each filament 201 to control the amount of current that flows to the filament 201. The gas supplied from the gas supplying portion 204 is exhausted through an exhaustion system.

The ions generated from the ion source 200 are extracted through an extraction electrode system 205 and the ion beam 122 is thus formed. The semiconductor substrate 119 disposed on a mounting board 206 is irradiated with the ion beam 122. The proportions of the ion species in the ion beam 122 are calculated with a mass spectrometer tube 207 disposed near the mounting board 206. The ion density calculated with the mass spectrometer tube 207 is converted into signals by using a mass spectrometer 208 and the results may be fed back to a power source controller 203. The power source controller 203 can control the filament power sources 202 in accordance with the calculation results on the ion density.

The gas such as hydrogen supplied from the gas supplying portion 204 flows through a chamber of the ion doping apparatus and is exhausted through the exhaustion system. Hydrogen supplied to the ion source 200 is ionized through the reaction represented by the formula (1):

H₂+e⁻→H₂⁺+2e⁻−Q(Q=15.39 eV) (1)

The pressure in the chamber of the ion doping apparatus is 1×10⁻² Pa to 1×10⁻¹ Pa and the ionization degree is not so high; therefore, a large amount of H₂ that is the source gas exist as compared with H₂⁺ ions. Therefore, H₂⁺ ions generated from the ion sources react with H₂ before the extraction through the extraction electrode system 205, and the reaction thereof is represented by formula (2):

H₂⁺+H₂→H₃⁺+H+Q(Q=1.49 eV) (2)

H₃⁺ exists as a more stable molecule than H⁺ and H₂⁺; therefore, as the proportion of collision with H₂ is higher, the larger amount of H₃⁺ are generated.

This is clear from the mass spectrometer result of the ion beam 122 flowing into the mounting board 206, with the use of the mass spectrometer tube 207; that is, the proportion of H₃⁺ ions to the total amount of ion species H⁺, H₂⁺, and H₃⁺ is equal to or more than 70%. Accordingly, the substrate is irradiated with the ion beam including a large amount of H₃⁺ that are cluster ions, which leads to advantageous effects of improving the introduction efficiency of hydrogen atoms and introducing hydrogen in the semiconductor substrate 119 at high concentration even if the dose is small, as compared to the case of irradiation with H⁺ or H₂⁺.

As described above, the increase in proportion of H₃⁺ enables the damaged layer 121 to include hydrogen at a concentration of 1×10²⁰ atoms/cm³ or more. In the damaged layer 121 formed in the semiconductor substrate 119, the crystal structure is damaged and microvoids are formed, so that a porous structure is formed. Therefore, the volume of microvoids formed in the damaged layer 121 is changed by thermal treatment at a relatively low temperature (600° C. or lower), and cleavage can be performed along the damaged layer 112 to obtain the single crystal semiconductor layer.

When a linear ion beam which is longer than one side of the semiconductor substrate 119 having an approximately rectangular shape scans the surface of the semiconductor substrate 119, the damaged layer 121 can be formed at uniform depth.

FIG. 8D shows a step of forming the insulating layer 102 over the first electrode 103. The insulating layer 102 is formed using an insulating film such as a silicon oxide film, a silicon oxynitride film, a silicon nitride oxide film, or a silicon nitride film. There is no limitation on the material for forming the insulating layer 102 as long as it is an insulating film, and a film having a smooth and hydrophilic surface may be used. As for the smoothness of the insulating layer 102, the average surface roughness (Ra) is preferably 1 nm or less, more preferably 0.5 nm or less. The “average surface roughness” in this specification refers to an average surface roughness obtained by three-dimensional expansion of centerline average roughness which is defined by JIS B0601 so as to be able to be applied to a plane.

Note that the silicon oxynitride film means a film that contains more oxygen than nitrogen in its composition and has composition ranges of oxygen, nitrogen, silicon, and hydrogen of 50 to 70 at. %, 0.5 to 15 at. %, 25 to 35 at. %, and 0.1 to 10 at. %, respectively in the measurement using Rutherford backscattering spectrometry (RBS) and hydrogen forward scattering (HFS). Further, the silicon nitride oxide film means a film that contains more nitrogen than oxygen in its composition and has composition ranges of oxygen, nitrogen, silicon, and hydrogen of 5 to 30 at. %, 20 to 55 at. %, 25 to 35 at. %, and 10 to 30 at. %, respectively in the measurement using RBS and HFS. Note that content ratios of nitrogen, oxygen, silicon, and hydrogen fall within the ranges given above when the total number of atoms contained in the silicon oxynitride film or the silicon nitride oxide film is defined as 100 at. %.

As silicon oxide containing hydrogen, for example, silicon oxide manufactured by a chemical vapor deposition method using organosilane is preferable. For example, by use of a silicon oxide film as the insulating layer 102 which is deposited using organosilane, a bond between the supporting substrate and a transported semiconductor layer can be made strong. For the organosilane, an organic compound which contains silicon, such as tetraethoxysilane (TEOS) (Si(OC₂H₅)₄), tetramethylsilane (TMS) (Si(CH₃)₄), tetramethylcyclotetrasiloxane (TMCTS), octamethylcyclotetrasiloxane (OMCTS), hexamethyldisilazane (HMDS), triethoxysilane (SiH(OC₂H₅)₃), or tris(dimethylamino)silane (SiH(N(CH₃)₂)₃) can be used.

Silicon nitride containing hydrogen can be manufactured by a plasma CVD method using a silane gas and an ammonia gas. Hydrogen may be added to the gases. Silicon nitride containing oxygen and hydrogen can be manufactured by a plasma CVD method using a silane gas, an ammonia gas, and a nitrous oxide gas. In any case, any of silicon oxide, silicon oxynitride, or silicon nitride oxide, which contains hydrogen and is deposited by a chemical vapor deposition method such as a plasma CVD method, a low-pressure CVD method, or an atmospheric-pressure CVD method using a silane gas or the like as a source gas, can be used. Recommended as the deposition temperature of the insulating layer 102 is equal to or less than 350° C. at which hydrogen is not desorbed from the damaged layer 121 formed in the single crystal semiconductor substrate.

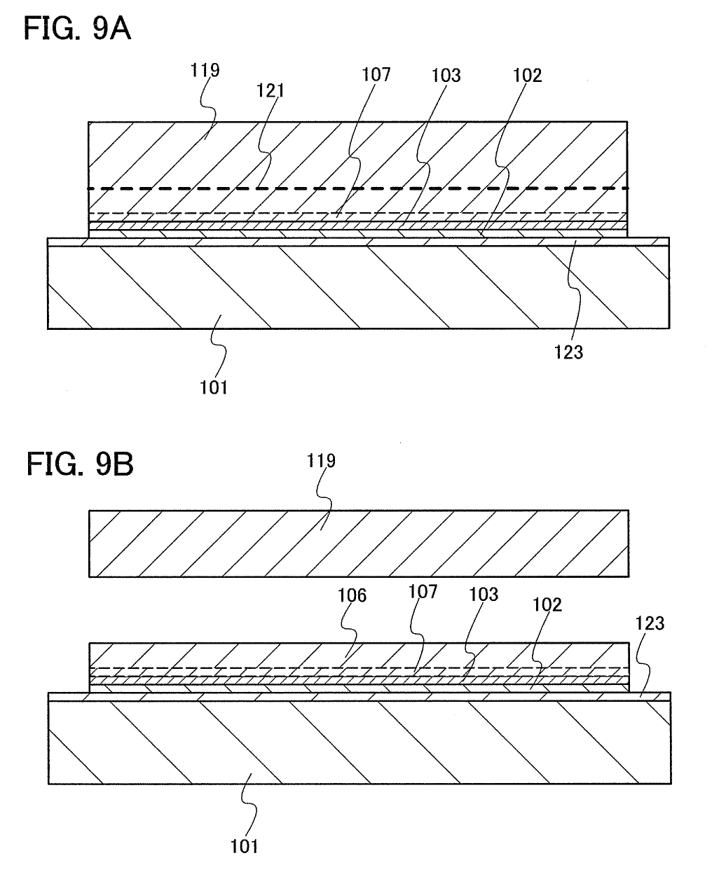

FIG. 9A shows a step of bonding the supporting substrate 101 and the semiconductor substrate 119 to each other. This bonding is formed in such a manner that the insulating layer 102 having a smooth and hydrophilic surface is firmly attached to the supporting substrate 101. This bond is formed by a hydrogen bond or van der Waals forces. When the substrate surface is hydrophilic, hydroxyl groups or water molecules serve as an adhesive. The water molecules are diffused by thermal treatment and the remaining components form silanol groups (Si—OH) to form the bonding by a hydrogen bond. Further, in this bonding portion, by hydrogen being released, a siloxane bond (a Si—O—Si bond) is formed to produce a covalent bond, so that the bonding between the semiconductor substrate 119 and the supporting substrate 101 can be made strong. Note that a silicon nitride film, a silicon nitride oxide film, or the like may be formed as a barrier layer 123 at a bonding surface of the supporting substrate 101. The provision of the barrier layer 123 can prevent contamination due to impurities from the supporting substrate 101.

In order to favorably perform the bonding between the supporting substrate 101 and the insulating layer 102, the bonding surfaces thereof is preferably activated in advance. For example, one or both of the bonding surfaces are irradiated with an atom beam or an ion beam. In the case of utilizing an atom beam or an ion beam, a neutral atom beam or an ion beam of an inert gas such as argon can be used. Alternatively, the bonding surfaces can be activated by performing plasma irradiation or radical treatment. Such surface treatment facilitates formation of bonding between different materials even at a temperature of 400° C. or less.

FIG. 9B shows a step of separating the semiconductor substrate 119 from the supporting substrate 101 by heat treatment with the damaged layer 121 serving as a cleavage plane. The heat treatment is performed preferably at a temperature which is equal to or more than the deposition temperature of the insulating layer 102 and equal to or less than the upper temperature limit of the supporting substrate 101. For example, the heat treatment is performed at 400° C. to 670° C., so that the volume of microvoids formed in the damaged layer 121 is changed and the semiconductor substrate 119 is cleaved along the region. Since the insulating layer 102 is bonded to the supporting substrate 101, the single crystal semiconductor layer 106 and the first electrode 103 remain over the supporting substrate 101. At this time, the thickness of the single crystal semiconductor layer 106 approximately corresponds to the depth at which the damaged layer 121 is formed, and the single crystal semiconductor layer 106 is formed to a thickness of equal to or more than 50 nm and less than 10000 nm, preferably 100 nm to 5000 nm.

Through the above-described steps, the single crystal semiconductor layer 106 which is fixed to the supporting substrate 101 by the insulating layer 102 can be provided.

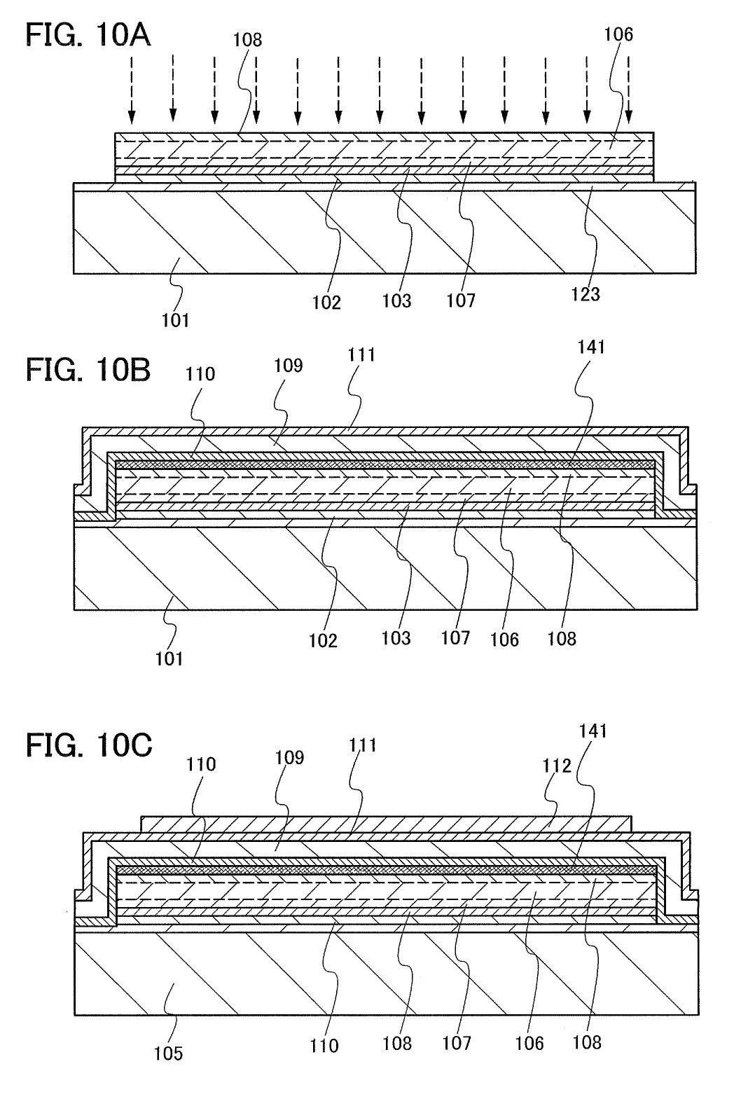

FIG. 10A shows a step of adding an impurity having a conductivity type opposite to that of the first impurity semiconductor layer 107, to the single crystal semiconductor layer 106 to form the second impurity semiconductor layer 108. For example, phosphorus or arsenic is added so that the second impurity semiconductor layer 108 has n-type conductivity. It is preferable that the surface of the single crystal semiconductor layer 106, which is closest to the damaged layer 121 or contains part of the damaged layer 121, is removed by etching; either dry etching or wet etching is performed.

Next, as shown in FIG. 10B, the intermediate layer 141, the third impurity semiconductor layer 110, the non-single-crystal semiconductor layer 109, and the fourth impurity semiconductor layer 111 are formed. The intermediate layer 141 is formed to a thickness of 1 nm to 50 nm. The third impurity semiconductor layer 110 is formed of a p-type amorphous semiconductor layer (such as a p-type amorphous silicon layer) or a p-type microcrystalline semiconductor layer (such as a p-type microcrystalline silicon layer) to have a thickness of 10 nm to 20 nm. The non-single-crystal semiconductor layer 109 is formed of an amorphous silicon layer to have a thickness of 100 nm to 300 nm (preferably 100 nm or more and 200 nm or less). The fourth impurity semiconductor layer 111 is formed of an n-type amorphous semiconductor layer (such as an n-type amorphous silicon layer) or an n-type microcrystalline semiconductor layer (such as an n-type microcrystalline silicon layer) to have a thickness of 20 nm to 60 nm.

The intermediate layer 141 is formed by a co-evaporation method. In the co-evaporation method, evaporation is performed in one chamber with use of a plurality of evaporation sources at the same time. The film formation is preferably performed in a low pressure atmosphere. The low pressure atmosphere is obtained by evacuating the chamber to vacuum by a vacuum evacuation means so that the degree of vacuum is 5×10⁻³ Pa or less, preferably about 10⁻⁴ Pa to 10⁻⁶ Pa.

The third impurity semiconductor layer 110, the non-single-crystal semiconductor layer 109, and the fourth impurity semiconductor layer 111 are formed by a plasma CVD method. As the electric power frequency for exciting plasma, a high-frequency electric power in the HF band or the VHF band of 10 MHz to 200 MHz, or a microwave electric power of 1 GHz to 5 GHz, typically 2.45 GHz, is applied. As a reactive gas containing a semiconductor source gas, a gas containing a hydride of silicon typified by silane or disilane, or a gas containing a fluoride of silicon or a chloride of silicon is used, and hydrogen or an inert gas is mixed with the gas as appropriate to be used. Diborane (B₂H₆) is added for controlling valence electron to provide p-type conductivity, and phosphine (PH₃) is used for controlling valence electron to provide n-type conductivity. Note that the amount of the impurity in the non-single crystal semiconductor layer 109 is preferably reduced, and oxygen and nitrogen are each contained at a concentration of 1×10¹⁹ /cm³ or less, preferably 5×10¹⁸ /cm³ or less.

As shown in FIG. 10C, the second electrode 112 is formed over the fourth impurity semiconductor layer 111. The second electrode 112 is formed using a transparent conductive material. As the transparent conductive material, metal oxide such as an indium tin oxide alloy (ITO), zinc oxide (ZnO), tin oxide (SnO₂), or an ITO-ZnO alloy is used. The thickness of the second electrode 112 is 40 nm to 200 nm (preferably 50 nm to 100 nm). The sheet resistance of the second electrode 112 may be about 20 to 200 ΩQ/square.

The second electrode 112 is formed by a sputtering method or a vacuum evaporation method. In this case, the second electrode 112 is formed using a shadow mask such that the second electrode 112 is selectively formed in a region where the first unit cell and the second unit cell overlap with each other. The third impurity semiconductor layer 110, the non-single-crystal semiconductor layer 109, and the fourth impurity semiconductor layer 111 are formed by a plasma CVD method over an entire surface of the supporting substrate 101; therefore, in the case where an unnecessary region thereof is removed, the second electrode 112 can be used as a mask for etching.

Note that a conductive macromolecular material (also called a “conductive polymer”) can be used instead of the above-described metal oxide in order to form the second electrode 112. As the conductive macromolecular material, π electron conjugated conductive macromolecule can be used. For example, polyaniline or derivatives thereof, polypyrrole or derivatives thereof, polythiophene or derivatives thereof, and copolymers of two or more kinds of those materials can be given.

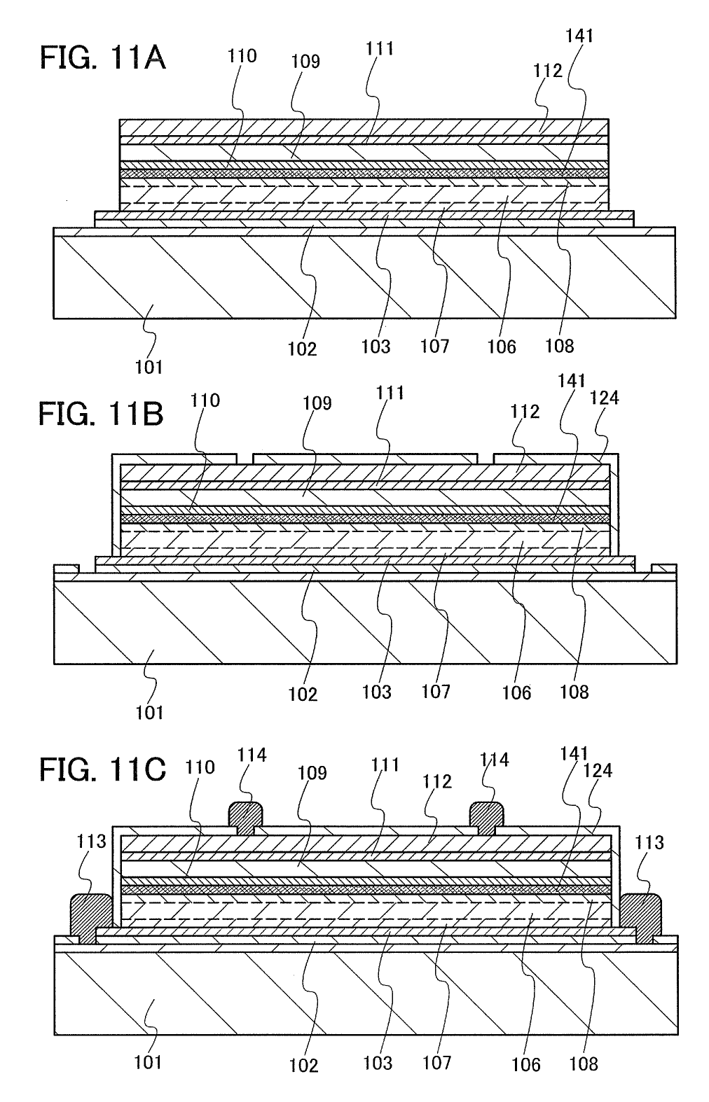

FIG. 11A shows a step of etching the fourth impurity semiconductor layer 111, the non-single-crystal semiconductor layer 109, the third impurity semiconductor layer 110, the second impurity semiconductor layer 108, the single crystal semiconductor layer 106, and the first impurity semiconductor layer 107 with the use of the second electrode 112 as a mask to expose an end portion of the first electrode 103. As the etching, dry etching is performed using a gas of NF₃, SF₆, or the like.

FIG. 11B shows a step of forming a passivation layer 124 which also serves as an anti-reflection layer over the supporting substrate 101 provided with the first unit cell 104 and the second unit cell 105. The passivation layer 124 is formed of silicon nitride, silicon nitride oxide, or magnesium fluoride. In order to form a contact between the passivation layer 124 and auxiliary electrodes, openings are formed in the passivation layer 124 such that parts of the surfaces of the first electrode 103 and the second electrode 112 are exposed. The openings of the passivation layer 124 are formed by an etching process. Alternatively, a passivation layer provided with openings is formed as the passivation layer 124; in this case, a method using a shadow mask as described above, or a lift-off method can be employed.

FIG. 11C shows a step of forming the first auxiliary electrode 113 which is in contact with the first electrode 103 and the second auxiliary electrode 114 which is in contact with the second electrode 112. As shown in FIG. 1, the second auxiliary electrode 114 is a comb-shaped or lattice-shaped electrode. The first auxiliary electrode 113 and the second auxiliary electrode 114 may be formed of aluminum, silver, lead-tin (solder), or the like. For example, the first auxiliary electrode 113 and the second auxiliary electrode 114 are formed by a screen printing method using a silver paste.

Through the above-described process, the photoelectric conversion device can be manufactured. According to the process in this embodiment mode, a technique of bonding different materials is used so that a photoelectric conversion device which includes a bottom cell including a single crystal semiconductor layer with a thickness of 10 μm or less as a photoelectric conversion layer and a top cell, which is stacked over the bottom cell, including a non-single-crystal semiconductor layer as a photoelectric conversion layer can be manufactured at a process temperature of 700° C. or less (preferably 500° C. or less). That is, the photoelectric conversion device can be manufactured which includes the bottom cell including the single crystal semiconductor layer as a photoelectric conversion layer and the top cell including the non-single-crystal semiconductor layer as a photoelectric conversion layer, which is stacked over the bottom cell, over a large-area glass substrate with an upper temperature limit of 700° C. or less. The single crystal semiconductor layer is obtained by separating a superficial portion of the single crystal semiconductor substrate. The single crystal semiconductor substrate can be used repeatedly, which leads to effective use of resources.

### Embodiment Mode 5

In Embodiment Mode 4, due to the formation of the damaged layer 121, crystal defects remain, in some cases, at the surface of the single crystal semiconductor layer 106 which is exposed through the separation of the semiconductor substrate 119 shown in FIG. 9B. In that case, it is preferable to remove a superficial portion of the single crystal semiconductor layer 106 by etching. As the etching, dry etching or wet etching can be performed. Further, in some cases, a cleavage plane of the single crystal semiconductor layer 106 may be uneven with an average surface roughness (Ra) of 7 nm to 10 nm and largest difference in height between peak and valley (P-V) is 300 nm to 400 nm. The “largest difference in height between peak and valley” in this specification refers to a difference in height between peak and valley. The “peak” and the “valley” in this embodiment mode refer to a peak and a valley obtained by three-dimensional expansion of the “peak” and the “valley” defined by JIS B0601. The peak is represented by the highest part of the peaks in the specified plane. The valley is represented by the lowest part of the valleys in the specified plane.

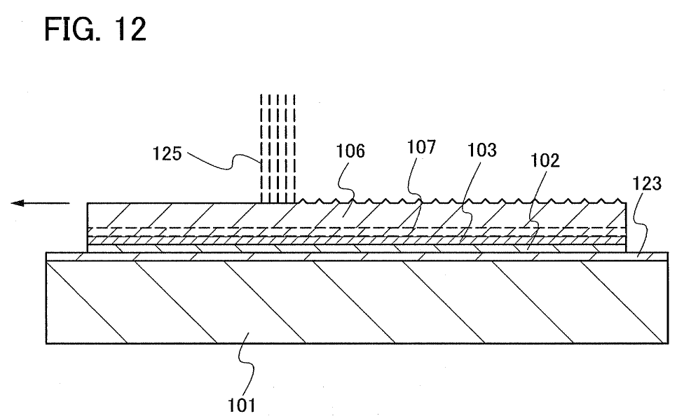

Furthermore, in order to repair the single crystal semiconductor layer 106 in which crystal defects remain, it is preferable to perform laser treatment. FIG. 12 shows the laser treatment performed on the single crystal semiconductor layer 106. The single crystal semiconductor layer 106 is irradiated with a laser beam 125, so that at least the surface side of the single crystal semiconductor layer 106 is melted and is recrystallized in the following cooling step, using a lower part of the single crystal semiconductor layer 106 in a solid-phase state as seed crystals; in this manner, defects of the single crystal semiconductor layer 106 can be repaired. Further, if the laser treatment is performed in an inert gas atmosphere, the surface of the single crystal semiconductor layer 106 can be planarized.

At the time of this laser treatment, the region to be irradiated with the laser beam is preferably heated at 250° C. to 600° C. When the region to be irradiated is heated, the melting time by the laser beam irradiation can be lengthened and defects can be repaired more effectively. The laser beam 125 melts the surface side of the single crystal semiconductor layer 106, but hardly heats the supporting substrate 101; thus, a supporting substrate the upper temperature limit of which is low, such as a glass substrate, can be used. In addition, since the first electrode 103 is formed of heat-resistant metal, the single crystal semiconductor layer 106 is not adversely affected even if the single crystal semiconductor layer 106 is heated at the above-described temperature. Silicide is formed at an interface between the metal and the first impurity semiconductor layer 107, so that current flows more easily. Activation of the second impurity semiconductor layer 108 can also be performed by this laser treatment.

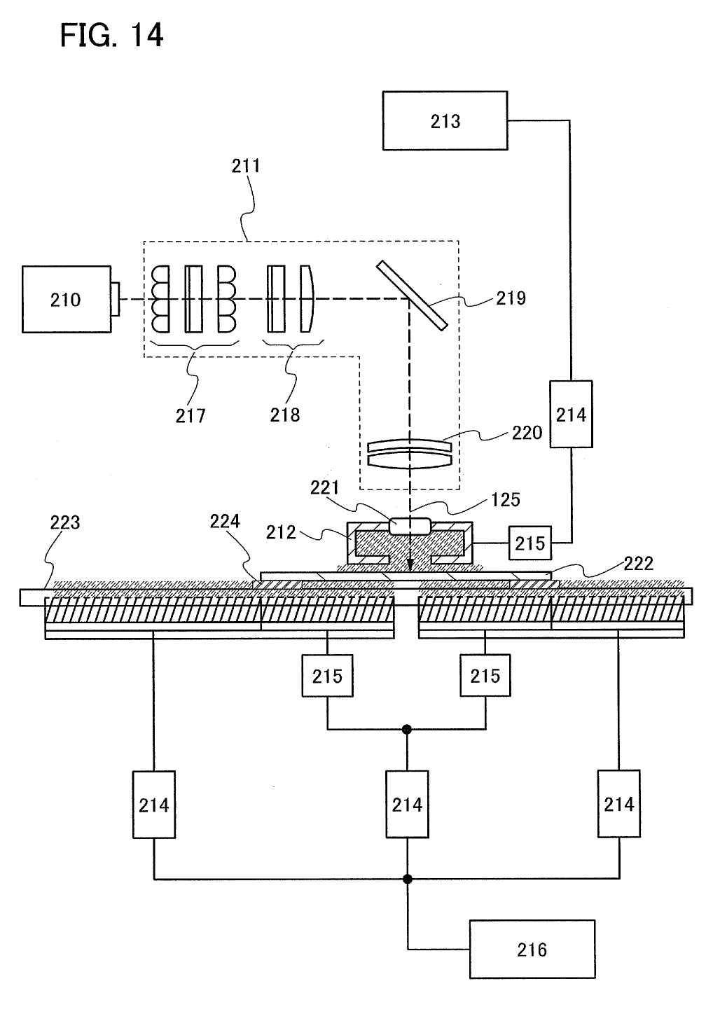

An example of a laser treatment apparatus for this laser treatment will be described with reference to FIG. 14. The laser treatment apparatus is provided with a laser oscillator 210, an optical system 211 which condenses and extends a laser beam into a thin linear beam, a gas jetting pipe 212 which controls the atmosphere of a region to be irradiated with a laser, a gas supply portion 213 which supplies a gas for controlling the atmosphere to the gas jetting pipe 212, a flow rate control portion 214, a gas heating portion 215, a substrate stage 222 which floats and carries the supporting substrate 101, a guide rail 223 which carries the substrate while supporting both ends of the substrate, and a gas supply portion 216 which supplies a gas for floating to the substrate stage 222.

As the laser oscillator 210, a laser which emits light with a wavelength in a range from ultra violet to visible light is selected. The laser oscillator 210 is preferably a pulsed ArF, KrF, or XeCl excimer laser, or a solid-state laser such as an Nd-YAG laser or YLF laser, with a repetition rate of 1 MHz or less and a pulse width of 10 ns or more and 500 ns or less. As the laser oscillator 210, a XeCl excimer laser with a repetition rate of 10 Hz to 300 Hz, a pulse width of 25 ns, and a wavelength of 308 nm can be used, for example.

The optical system 211 condenses and extends a laser beam to form a laser beam a cross-section of which has a linear shape on a surface to be irradiated. The optical system 211 which forms a linear beam includes a cylindrical lens array 217, a cylindrical lens 218, a mirror 219, and a doublet cylindrical lens 220. The linear laser beam of about 100 mm to 700 mm in a longer direction and about 100 μm to 500 μm in a shorter direction can be emitted, though it depends on the size of the lens.

The supporting substrate 101 is irradiated with the laser beam condensed into a linear shape through a light introduce window 221 of the gas jetting pipe 212. The gas jetting pipe 212 is provided in vicinity to the supporting substrate 101. A nitrogen gas is supplied to the gas jetting pipe 212 from the gas supply portion 213. The nitrogen gas is jetted from an opening portion of the gas jetting pipe 212, which faces the supporting substrate 101. The opening portion of the gas jetting pipe 212 is provided in accordance with an optical axis of the linear laser beam so that the supporting substrate 101 is irradiated with the laser beam which enters through the light introduce window 221. Due to the nitrogen gas jetted from the opening portion of the gas jetting pipe 212, a region to be irradiated with the laser beam has a nitrogen atmosphere.

The temperature of a surface of the supporting substrate 101, which is to be irradiated with the laser beam, can be controlled with the nitrogen gas which is supplied to the gas jetting pipe 212 and heated up to 250° C. to 600° C. in the gas heating portion 215. By heating the region to be irradiated, the melting time due to the laser beam irradiation can be controlled as described above.

Air or nitrogen is supplied to the substrate stage 222 from the gas supply portion 216 through the flow rate control portion 214. A gas supplied from the gas supply portion 216 is jetted so that a bottom surface of the supporting substrate 101 is sprayed with the gas from a top surface of a substrate stage 222; in this manner, the supporting substrate 101 is floated. The supporting substrate 101 is carried with its both ends mounted on a slider 224 which moves over the guide rail 223. By being sprayed with the gas from the substrate stage 222 side, the substrate can be carried in a floating state without a bend. In the laser treatment apparatus of this embodiment mode, the top surface of the supporting substrate 101 is sprayed with the nitrogen gas from the gas jetting pipe 212; therefore, when the rear side of the supporting substrate 101 is also sprayed with gas, the supporting substrate 101 can be prevented from being curved.

The substrate stage 222 can be divided into a region including a laser irradiation portion and its vicinity, and the other region. The laser irradiation portion and its vicinity of the substrate stage 222 can be sprayed with a nitrogen gas heated by the gas heating portion 215, so that the supporting substrate 101 can be heated.

The laser treatment shown in FIG. 12 is effective in terms of repairing defects of the single crystal semiconductor layer 106. That is, in a photoelectric conversion device, carriers (electrons and holes) generated in a semiconductor by photoelectric conversion are collected in an electrode formed over a surface of a semiconductor layer and extracted as current. At this time, if the number of recombination centers at the surface of the semiconductor layer is large, photogenerated carriers are quenched there, which becomes a cause of deteriorating photoelectric conversion characteristic. Thus, repairing defects of the single crystal semiconductor layer by laser treatment is effective.

### Embodiment Mode 6

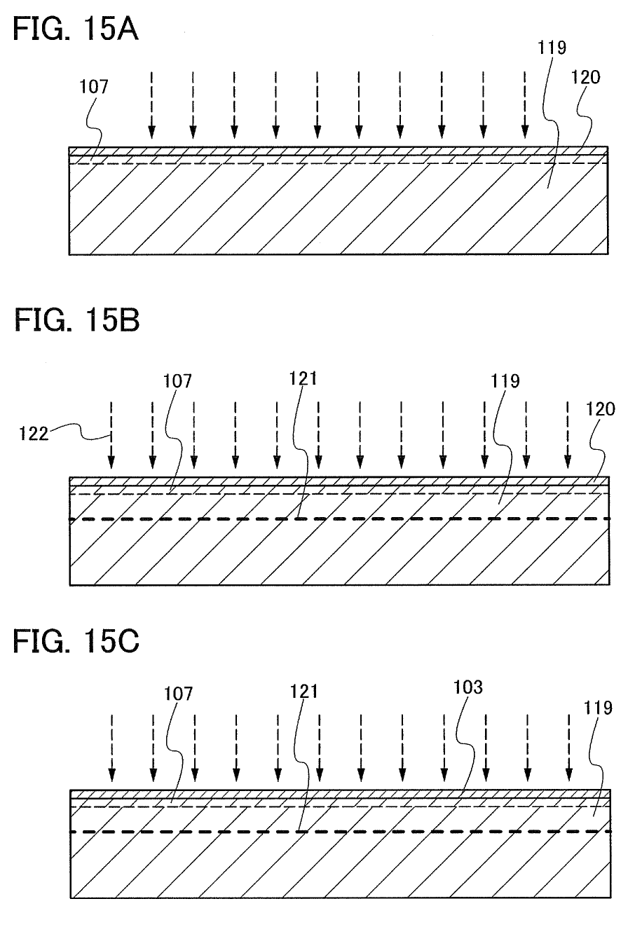

In this embodiment mode, manufacturing steps which are different from those in Embodiment Mode 1 will be described with reference to FIGS. 15A to 15C. The protection film 120 and the first impurity semiconductor layer 107 are formed (FIG. 15A), and then, the damaged layer 121 may be formed with the protection film 120 left as it is (FIG. 15B). After that, the protection film 120 is removed and the first electrode 103 is formed (FIG. 15C). Such steps make it possible to effectively use the protection film 120. That is, the protection film 120 damaged due to the ions irradiation is removed before the first electrode 103 is formed, so that the surface of the semiconductor substrate 119 can be prevented from being damaged. In addition, since the damaged layer 121 into which cluster ions of hydrogen are introduced is formed through the first impurity semiconductor layer 107, hydrogenation of the first impurity semiconductor layer 107 can also be performed.

### Embodiment Mode 7

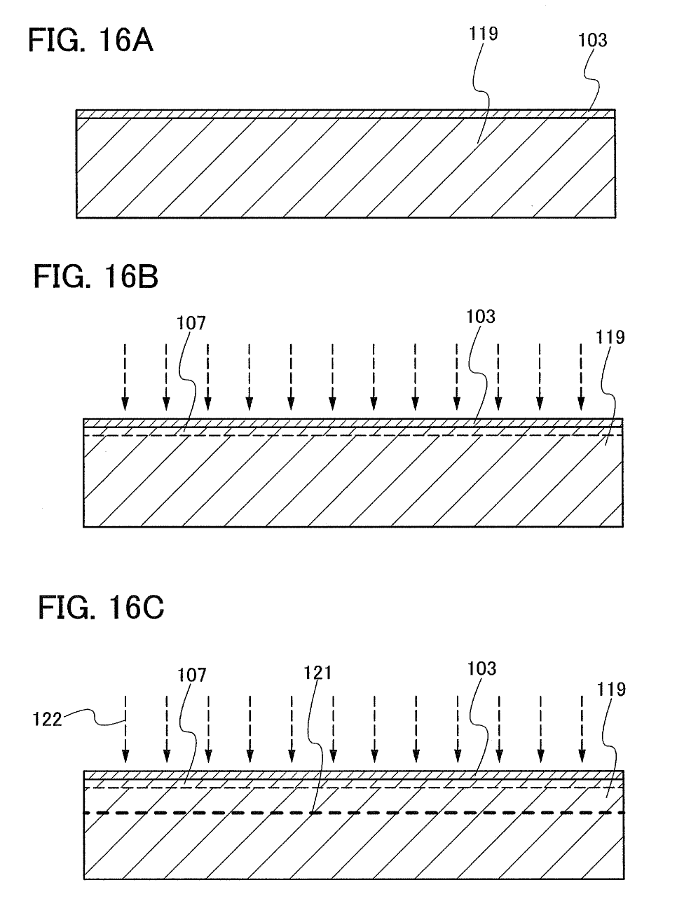

In this embodiment mode, manufacturing steps which are different from those in Embodiment Mode 1 will be described with reference to FIGS. 16A to 16C. The first electrode 103 is formed over the semiconductor substrate 119 (FIG. 16A), and an impurity which imparts one conductivity type is added through the first electrode 103 to form the first impurity semiconductor layer 107 (FIG. 16B). Then, cluster ions of hydrogen are introduced through the first electrode 103 to form the damaged layer 121 (FIG. 16C). In this process, the first electrode 103, which is formed first, can be used as a damage preventing layer during ion doping. In addition, a step of forming a protection film for the ion doping can be omitted. In addition, since the damaged layer 121 into which cluster ions of hydrogen are introduced is formed through the first impurity semiconductor layer 107, hydrogenation of the first impurity semiconductor layer 107 can also be performed.

### Embodiment Mode 8

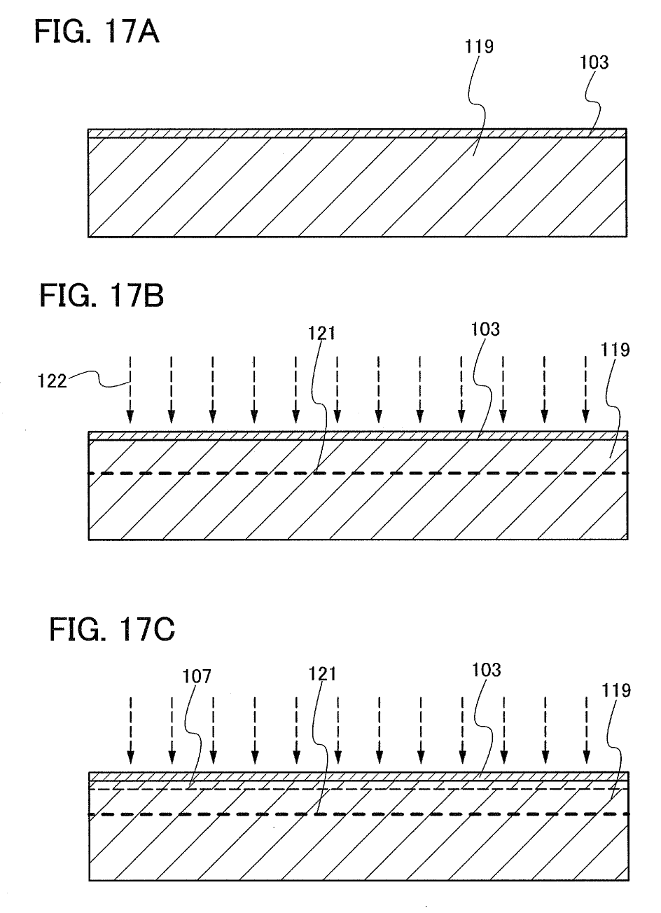

In this embodiment mode, manufacturing steps which are different from those in Embodiment Mode 1 will be described with reference to FIGS. 17A to 17C. The first electrode 103 is formed over the semiconductor substrate 119 (FIG. 17A), and cluster ions of hydrogen are introduced through the first electrode 103 to form the damaged layer 121 (FIG. 17B). Then, an impurity which imparts one conductivity type is added through the first electrode 103 to form the first impurity semiconductor layer 107 (FIG. 17C). In this process, the first electrode 103, which is formed first, can be used as a damage preventing layer during ion doping. In this embodiment mode, a step of forming a protection film for the ion doping can be omitted.

### Embodiment Mode 9

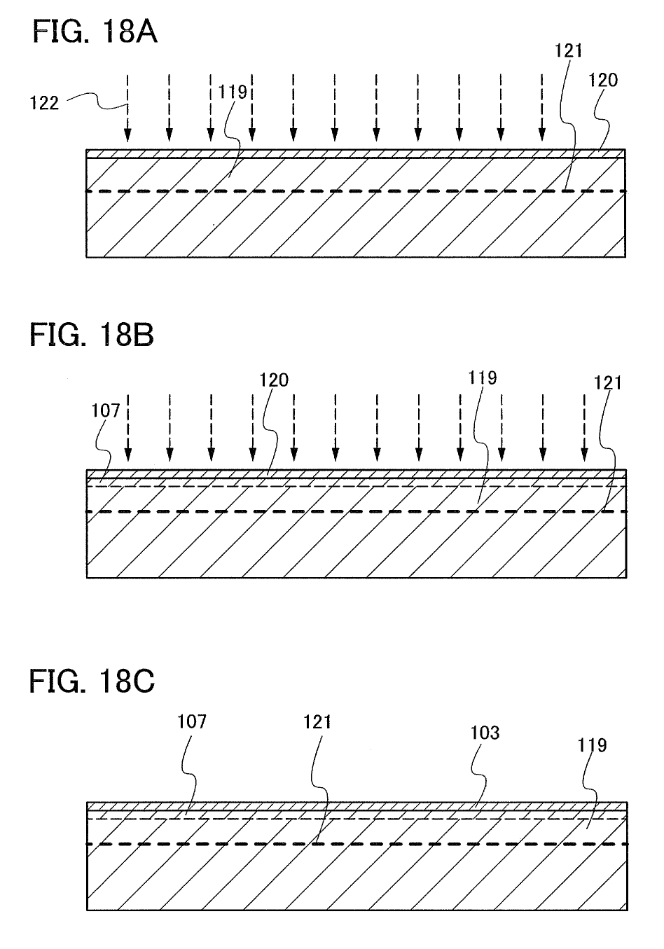

In this embodiment mode, manufacturing steps which are different from those in Embodiment Mode 1 will be described with reference to FIGS. 18A to 18C. The protection film 120 is formed, and cluster ions of hydrogen are introduced to form the damaged layer 121 (FIG. 18A), and the first impurity semiconductor layer 107 is formed with the protection film 120 left as it is (FIG. 18B). Then, the protection film 120 is removed and the first electrode 103 is formed (FIG. 18C). Such steps make it possible to effectively use the protection film 120. In addition, since the first impurity semiconductor layer 107 is formed after the damaged layer 121 is formed, the impurity concentration of the first impurity semiconductor layer 107 can be increased and a shallow junction can be formed. Accordingly, a photoelectric conversion device which has high collection efficiency of photogenerated carriers by back surface field (BSF) effect can be manufactured.

### Embodiment Mode 10

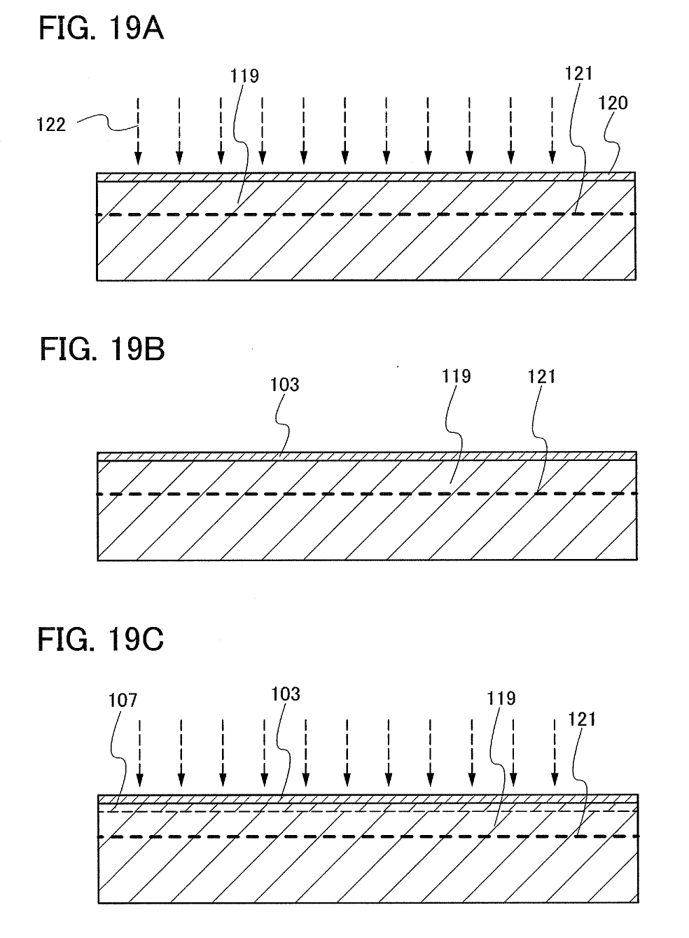

In this embodiment mode, manufacturing steps which are different from those in Embodiment Mode 1 will be described with reference to FIGS. 19A to 19C. The protection film 120 is formed and cluster ions of hydrogen are introduced to form the damaged layer 121 (FIG. 19A), and the protection film 120 is removed and the first electrode 103 is formed (FIG. 19B). Then, an impurity which imparts one conductivity type is added through the first electrode 103 to form the first impurity semiconductor layer 107 (FIG. 19C). Since the first impurity semiconductor layer 107 is formed through the first electrode 103, the thickness of the first impurity semiconductor layer 107 can be easily controlled.

### Embodiment Mode 11

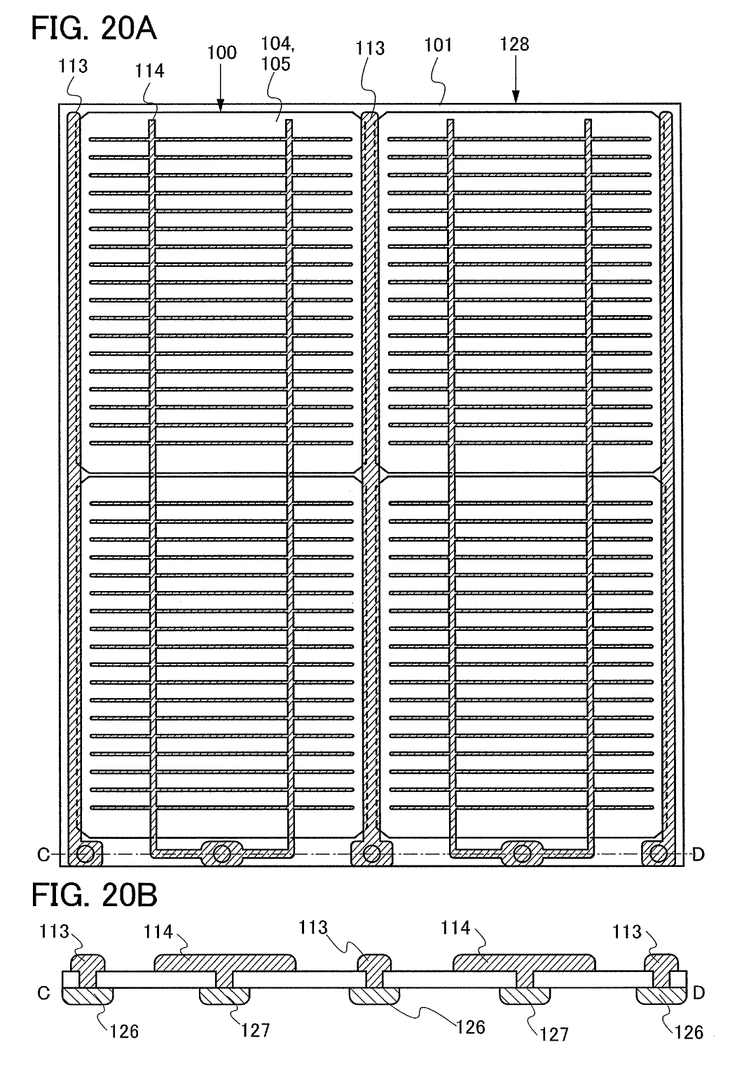

An example of a photovoltaic power generation module using any of the photoelectric conversion devices manufactured according to Embodiment Modes 1 to 10 is shown in FIG. 20A. This photovoltaic power generation module 128 includes the first unit cell 104 and the second unit cell 105 provided over the supporting substrate 101.

The first auxiliary electrode 113 and the second auxiliary electrode 114 are formed over one surface of the supporting substrate 101, and connected to a first rear electrode 126 and a second rear electrode 127 each for connector, respectively at end regions of the supporting substrate 101. FIG. 20B is a cross-sectional view taken along section line C-D of FIG. 20A. The first auxiliary electrode 113 is connected to the first rear electrode 126 and the second auxiliary electrode 114 is connected to the second rear electrode 127 through pass-through openings of the supporting substrate 101.

The photoelectric conversion device 100 is manufactured in which the first supporting substrate 101 is provided with the first unit cell 104 and the second unit cell 105 as described above, whereby reduction in thickness of the photovoltaic power generation module 128 can be achieved.

### Embodiment Mode 12

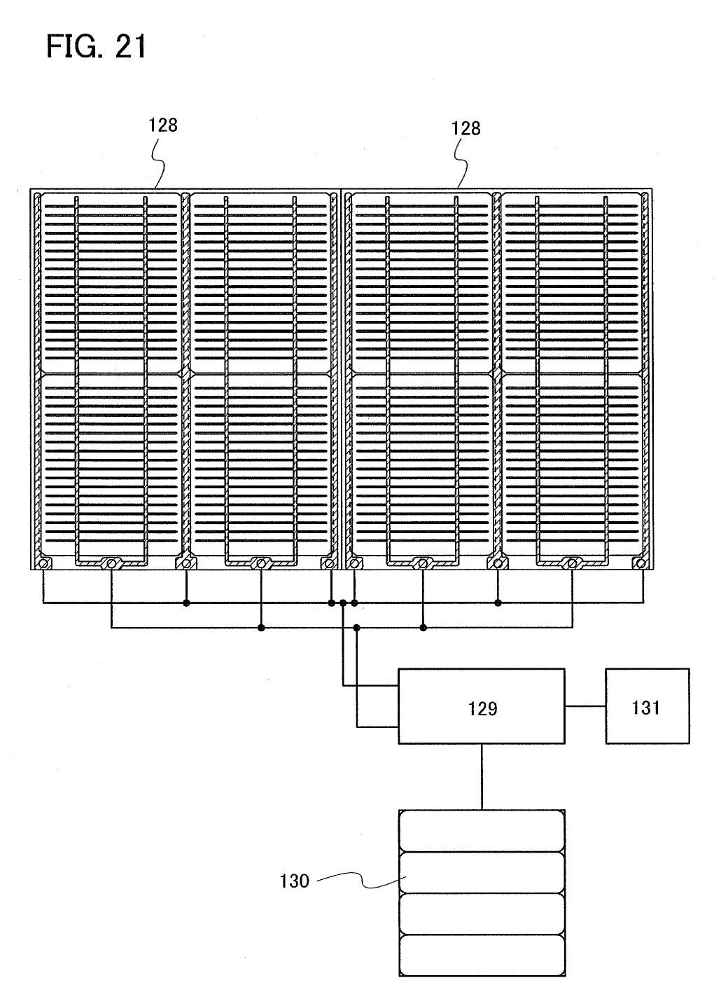

FIG. 21 shows an example of a photovoltaic power generation system using the photovoltaic power generation module 128. Output power of one or a plurality of photovoltaic power generation modules 128 charges a storage battery 130 with a charge control circuit 129. If the charged amount of the storage battery 130 is large, the output power is directly outputted to a load 131 in some cases.

When an electric double layer capacitor is used for the storage battery 130, a chemical reaction is not needed for charging and the battery can be charged rapidly and the lifetime of the storage battery 130 can be increased by about 8 times and the charge-discharge efficiency thereof can be increased by 1.5 times in comparison with a lead battery or the like which uses a chemical reaction. The load 131 can be used for a variety of purposes including lighting such as a fluorescent lamp, a light-emitting diode, or an electroluminescent panel, and a small-size electronic device.

This application is based on Japanese Patent Application serial no. 2007-308488 filed with Japan Patent Office on Nov. 29, 2007, the entire contents of which are hereby incorporated by reference.

What is claimed is:

1. A photoelectric conversion device comprising:
a first electrode over a substrate;
a first unit cell including a single crystal semiconductor layer over the first electrode;
an intermediate layer over the first unit cell;
a second unit cell including a semiconductor layer over the intermediate layer; and
a second electrode over the second unit cell,
wherein the semiconductor layer includes a first impurity semiconductor layer, a second impurity semiconductor layer and a non-single-crystal semiconductor layer interposed between the first and second impurity semiconductor layers, and
wherein the first impurity semiconductor layer has one conductivity type and the second impurity semiconductor layer has a conductivity type opposite to the conductivity type of the first impurity semiconductor layer.

2. The photoelectric conversion device according to claim 1,
wherein the intermediate layer includes a transition metal oxide, and
wherein the transition metal oxide is an oxide of a metal belonging to any of Groups 4 to 8 in a periodic table.

3. The photoelectric conversion device according to claim 2,
wherein the transition metal oxide is the group consisting of vanadium oxide, niobium oxide, tantalum oxide, chromium oxide, molybdenum oxide, tungsten oxide, manganese oxide, and rhenium oxide.

4. The photoelectric conversion device according to claim 1,
wherein the intermediate layer includes a transition metal oxide and an organic compound.

5. The photoelectric conversion device according to claim 4,
wherein the organic compound is the group consisting of an aromatic amine compound, a carbazole derivative, an aromatic hydrocarbon, and a macromolecular compound.

6. The photoelectric conversion device according to claim 1,
wherein the intermediate layer includes a first layer having a composite material of a transition metal oxide and an organic compound and a second layer having a transition metal oxide, and
wherein the first layer and the second layer are stacked.

7. The photoelectric conversion device according to claim 1,
wherein the intermediate layer comprises a first layer including a transition metal oxide, a second layer including a composite material of a transition metal oxide and an organic compound, and a third layer including a transition metal oxide, and
wherein the second layer is interposed between the first layer and the third layer.

8. The photoelectric conversion device according to claim 1,
wherein the single crystal semiconductor layer has a thickness of 0.1 μm or more and 10 μm or less.

9. The photoelectric conversion device according to claim 1,
wherein the single crystal semiconductor layer is a single crystal silicon layer and the non-single-crystal semiconductor layer is an amorphous silicon layer.

10. The photoelectric conversion device according to claim 1,
wherein the first unit cell includes a third impurity semiconductor layer and a fourth impurity semiconductor layer,
wherein the single crystal semiconductor layer is interposed between the third impurity semiconductor layer and the fourth impurity semiconductor layer, and
wherein the third impurity semiconductor layer has one conductivity type and the fourth impurity semiconductor layer has a conductivity type opposite to the conductivity type of the third impurity semiconductor layer.

11. A photoelectric conversion device comprising:
a first electrode over a substrate;
a first unit cell including a single crystal semiconductor layer over the first electrode;
a first intermediate layer over the first unit cell;
a second unit cell including a first semiconductor layer over the first intermediate layer;
a second intermediate layer over the second unit cell;
a third unit cell including a second semiconductor layer over the second intermediate layer; and
a second electrode over the third unit cell,
wherein the first semiconductor layer includes a first impurity semiconductor layer, a second impurity semiconductor layer and a first non-single-crystal semiconductor layer interposed between the first and second impurity semiconductor layers,
wherein the second semiconductor layer includes a third impurity semiconductor layer, a fourth impurity semiconductor layer and a second non-single-crystal semiconductor layer interposed between the third and fourth impurity semiconductor layers,
wherein the first impurity semiconductor layer has one conductivity type and the second impurity semiconductor layer has a conductivity type opposite to the conductivity type of the first impurity semiconductor layer, and
wherein the third impurity semiconductor layer has one conductivity type and the fourth impurity semiconductor layer has a conductivity type opposite to the conductivity type of the third impurity semiconductor layer.

12. The photoelectric conversion device according to claim 11,
wherein at least one of the first and second intermediate layers includes a transition metal oxide, and
wherein the transition metal oxide is an oxide of a metal belonging to any of Groups 4 to 8 in a periodic table.

13. The photoelectric conversion device according to claim 12,
wherein the transition metal oxide is any of vanadium oxide, niobium oxide, tantalum oxide, chromium oxide, molybdenum oxide, tungsten oxide, manganese oxide, and rhenium oxide.

14. The photoelectric conversion device according to claim 11,
wherein at least one of the first and second intermediate layers includes a transition metal oxide and an organic compound.

15. The photoelectric conversion device according to claim 14,
wherein the organic compound is the group consisting of an aromatic amine compound, a carbazole derivative, an aromatic hydrocarbon, and a macromolecular compound.

16. The photoelectric conversion device according to claim 11,
wherein at least one of the first and second intermediate layers includes a first layer having a composite material of a transition metal oxide and an organic compound and a second layer having a transition metal oxide, and
wherein the first layer and the second layer are stacked.

17. The photoelectric conversion device according to claim 11,
wherein at least one of the first and second intermediate layers comprises a first layer including a transition metal oxide, a second layer including a composite material of a transition metal oxide and an organic compound, and a third layer including a transition metal oxide, and
wherein the second layer is interposed between the first layer and the third layer.

18. The photoelectric conversion device according to claim 11,
wherein the first semiconductor layer has a thickness of 0.1 μm or more and 10 μm or less.

19. The photoelectric conversion device according to claim 11,
wherein the single crystal semiconductor layer is single crystal silicon, the first non-single-crystal semiconductor layer is microcrystal silicon, and the second non-single-crystal semiconductor layer is amorphous silicon.

20. The photoelectric conversion device according to claim 11,
wherein the single crystal semiconductor layer is single crystal silicon, the first non-single-crystal semiconductor layer is amorphous silicon, and the second non-single-crystal semiconductor layer is microcrystal silicon.

21. The photoelectric conversion device according to claim 11,
wherein the first unit cell includes a fifth impurity semiconductor layer and a sixth impurity semiconductor layer,
wherein the single crystal semiconductor layer is interposed between the fifth impurity semiconductor layer and the sixth impurity semiconductor layer, and
wherein the fifth impurity semiconductor layer has one conductivity type and the sixth impurity semiconductor layer has a conductivity type opposite to the conductivity type of the fifth impurity semiconductor layer.

22. A method for manufacturing a photoelectric conversion device, comprising the steps of:
introducing a cluster ion into a single crystal semiconductor substrate through one surface of the single crystal semiconductor substrate to form a damaged layer;
forming a first impurity semiconductor layer on the one surface of single crystal semiconductor substrate, wherein the first impurity semiconductor layer has one conductivity type;
forming a first electrode over the first impurity semiconductor layer;
forming an insulating layer over the first electrode;
bonding the insulating layer to a supporting substrate;
cleaving the single crystal semiconductor substrate at the damaged layer, so that a single crystal semiconductor layer remains over the supporting substrate;
forming a second impurity semiconductor layer on a cleavage plane side of the single crystal semiconductor layer, wherein the second impurity semiconductor layer has a conductivity type opposite to the conductivity type of the first impurity semiconductor layer;
forming an intermediate layer over the second impurity semiconductor layer;
forming a third impurity semiconductor layer over the intermediate layer, wherein the third impurity semiconductor layer has one conductivity type;
forming a non-single-crystal semiconductor layer over the third impurity semiconductor layer;
forming a fourth impurity semiconductor layer over the non-single-crystal semiconductor layer, wherein the fourth impurity semiconductor layer has a conductivity type opposite to the conductivity type of the third impurity semiconductor layer; and
forming a second electrode over the fourth impurity semiconductor layer.

23. The method for manufacturing a photoelectric conversion device according to claim 22,
wherein the cluster ion is a hydrogen ion and larger in mass than a hydrogen molecular, and
wherein the cluster ion is introduced by irradiating the single crystal semiconductor substrate with an ion beam containing the cluster ion by 50% or more.

24. The method for manufacturing a photoelectric conversion device according to claim 22, wherein the damaged layer is formed at a depth of 10 μm or less from the one surface of single crystal semiconductor substrate.

25. The method for manufacturing a photoelectric conversion device according to claim 22, wherein the intermediate layer is formed by co-evaporation method to include a transition metal oxide and an organic compound.

26. The method for manufacturing a photoelectric conversion device according to claim 22,
wherein the intermediate layer includes a first layer having a composite material of a transition metal oxide and an organic compound and a second layer having a transition metal oxide, and
wherein the first layer and the second layer are stacked.

27. The method for manufacturing a photoelectric conversion device according to claim 22,
wherein the intermediate layer comprises a first layer including a transition metal oxide, a second layer including a composite material of a transition metal oxide and an organic compound, and a third layer including a transition metal oxide, and
wherein the second layer is interposed between the first layer and the third layer.

28. A method for manufacturing a photoelectric conversion device, comprising the steps of:
introducing a cluster ion into a single crystal semiconductor substrate through one surface of the single crystal semiconductor substrate to form a damaged layer;
forming a first impurity semiconductor layer on the one surface of single crystal semiconductor substrate, wherein the first impurity semiconductor layer has one conductivity type;
forming a first electrode over the first impurity semiconductor layer;
forming an insulating layer over the first electrode;
bonding the insulating layer to a supporting substrate;
cleaving the single crystal semiconductor substrate at the damaged layer, so that a single crystal semiconductor layer remains over the supporting substrate;
forming a second impurity semiconductor layer on a cleavage plane side of the single crystal semiconductor layer, wherein the second impurity semiconductor layer has a conductivity type opposite to the conductivity type of the first impurity semiconductor layer;
forming a first intermediate layer over the second impurity semiconductor layer;
forming a third impurity semiconductor layer over the first intermediate layer, wherein the third impurity semiconductor layer has one conductivity type;
forming a first non-single-crystal semiconductor layer over the third impurity semiconductor layer;
forming a fourth impurity semiconductor layer over the first non-single-crystal semiconductor layer, wherein the second impurity semiconductor layer has a conductivity type opposite to the conductivity type of the first impurity semiconductor layer;
forming a second intermediate layer over the fourth impurity semiconductor layer;
forming a fifth impurity semiconductor layer over the second intermediate layer, wherein the fifth impurity semiconductor layer has one conductivity type;
forming a second non-single-crystal semiconductor layer over the fifth impurity semiconductor layer;
forming a sixth impurity semiconductor layer over the second non-single-crystal semiconductor layer, wherein the sixth impurity semiconductor layer has a conductivity type opposite to the conductivity type of the fifth impurity semiconductor layer; and
forming a second electrode over the sixth impurity semiconductor layer.

29. The method for manufacturing a photoelectric conversion device according to claim 28,
wherein the cluster ion is a hydrogen ion and larger in mass than a hydrogen molecular, and
wherein the cluster ion is introduced by irradiating the single crystal semiconductor substrate with an ion beam containing the cluster ion by 50% or more.

30. The method for manufacturing a photoelectric conversion device according to claim 28, wherein the damaged layer is formed at a depth of 10 μm or less from the one surface of single crystal semiconductor substrate.

31. The method for manufacturing a photoelectric conversion device according to claim 28, wherein at least one of the first and second intermediate layers is formed by co-evaporation method to include a transition metal oxide and an organic compound.

32. The method for manufacturing a photoelectric conversion device according to claim 28,
wherein at least one of the first and second intermediate layers includes a first layer having a composite material of a transition metal oxide and an organic compound and a second layer having a transition metal oxide, and
wherein the first layer and the second layer are stacked.

33. The method for manufacturing a photoelectric conversion device according to claim 28,
wherein at least one of the first and second intermediate layers comprises a first layer including a transition metal oxide, a second layer including a composite material of a transition metal oxide and an organic compound, and a third layer including a transition metal oxide, and
wherein the second layer is interposed between the first layer and the third layer.
